(19) United States
(12) Patent Application Publication
(10) Pub. No.: US 2015/0001576 A1
(43) Pub. Date: Jan. 1, 2015

(54) ELECTRO-OPTICAL DEVICE, MANUFACTURING METHOD OF ELECTRO-OPTICAL DEVICE AND ELECTRONIC APPARATUS

(71) Applicant: SEIKO EPSON CORPORATION, Tokyo (JP)

(72) Inventor: Shinichi IWATA, Chino-shi (JP)

(21) Appl. No.: 14/312,436

(22) Filed: Jun. 23, 2014

(30) Foreign Application Priority Data
Jun. 28, 2013 (JP) 2013-136040

(51) Int. Cl. H01L 33/52; H01L 51/52; H01L 51/56; H01L 33/58; H01L 33/00

(52) U.S. Cl. CPC H01L 33/52; H01L 33/58; H01L 33/005; H01L 51/56; H01L 51/5237; H01L 2933/005
USPC 257/100; 438/26

(57) ABSTRACT

An organic EL device includes an element substrate; light-emitting elements which are provided on the element substrate and contain a light-emitting functional layer; a sealing layer which is provided to cover the light-emitting elements; and a color filter layer which is provided on the sealing layer and is formed of a resin material, in which the sealing layer includes a convex portion which is arranged on an outer edge portion to surround a center portion of the sealing layer and has a greater film thickness than that of the center portion.

### BACKGROUND

1. Technical Field

The present invention relates to an electro-optical device, a manufacturing method of an electro-optical device and an electronic apparatus.

2. Related Art

In an organic Electro-Luminescence (EL) device, a light-emitting element, in which a light-emitting functional layer is sandwiched between an anode and a cathode, is provided on an element substrate. Many of the materials used for the light-emitting functional layer react easily with water and oxygen in the atmosphere and are degraded. Therefore, technology known as a thin film sealing structure, in which the penetration of water or oxygen is prevented by arranging a buffer layer and a gas barrier layer to cover the light-emitting element, is used. The thin film sealing structure (the buffer layer and the gas barrier layer) is arranged, for example, over a wider range than a light-emitting region, in which the light-emitting elements are set in an array on the element substrate. Color filters are, for example, provided on an opposing substrate, which is arranged to oppose the light-emitting elements on the element substrate.

When the organic EL device is used as a display device of a miniature electronic apparatus such as a Head Mounted Display (HMD), for example, there is demand for an increase in the definition of pixels and minimization of a frame region (a region of the periphery of the light-emitting region that does not actually contribute to light-emission). In order to increase the definition of the pixels, it is necessary to suppress the positional shifting to be small between the light-emitting elements and the color filters. Therefore, an on-chip color filter structure is proposed, in which the color filters are formed on the thin film sealing structure of the element substrate instead of the opposing substrate (for example, refer to JP-A-2012-38677).

In the organic EL device disclosed in JP-A-2012-38677, color filters with a plurality of coloring layers are formed on the thin film sealing structure that contains a planarization layer (the buffer layer) formed of a resin material and a sealing layer (the gas barrier layer) formed of an inorganic material. The plurality of coloring layers and partitioning walls that partition the coloring layers (the pixel regions) from one another are formed of a resin material such as an acrylic. When forming the color filters, the coloring layer is applied to the entire surface on the element substrate, that is, up to further outside than the outer peripheral portion of the thin film sealing structure; and, subsequently, portions of the coloring layer other than the light-emitting region are removed.

Incidentally, in the organic EL device with an on-chip color filter structure that is disclosed in JP-A-2012-38677, when the resin material of the coloring layer, which is applied to the entire surface on the thin film sealing structure, is leveled by being spread, the film thickness of the resin material becomes thin in the proximity of the level difference between the resin material and the element substrate in the outer peripheral portion of the thin film sealing structure. When the frame region of the organic EL device is small, the distance between the outer peripheral portion of the light-emitting region and the outer peripheral portion of the element substrate also becomes small; thus, the distance between the outer peripheral portion of the light-emitting region and the outer peripheral portion of the thin film sealing structure, that is, the distance between the outer peripheral portion of the color filters and the outer peripheral portion of the thin film sealing structure is also reduced. As a result, since the film thickness of the coloring layer (the color filters) is thinner at the outer edge portion in comparison to at the center portion in the light-emitting region, there is a problem in that light-emission irregularity (color irregularity or luminance irregularity) occurs, causing a reduction in the display quality of the organic EL device.

### SUMMARY

The invention can be realized in the following forms or application examples.

### Application Example 1

According to this application example, there is provided an electro-optical device that includes a substrate; light-emitting elements which are provided above the substrate and contain a first electrode, a second electrode that is arranged to oppose the first electrode and an organic light-emitting layer that is arranged between the first electrode and the second electrode; a sealing layer which is provided above the light-emitting elements to cover the light-emitting elements; and an optical layer which is provided above the sealing layer and formed of a resin material. The sealing layer includes a convex portion which is arranged on an outer edge portion to surround a center portion of the sealing layer and has a greater film thickness than that of the center portion.

According to the configuration of this application example, the sealing layer that covers the light-emitting elements includes the convex portion, which is formed on the outer edge portion to have a greater film thickness than that of the center portion, and the optical layer that is formed of a resin material is provided on the sealing layer. Therefore, when forming the optical layer, when the resin material is applied to the entire surface on the element substrate, the resin material is arranged to extend over the convex portion of the sealing layer; however, even if the resin material that is arranged on the outside of the convex portion is leveled in the proximity of the level difference between the outer peripheral portion and the element substrate, the resin material that is arranged on the inside of the convex portion is prevented from spreading to the outside by the convex portion. Accordingly it is possible to render the film thickness of the optical layer that is formed inside of the convex portion uniform in comparison with a case in which the convex portion is not present. Accordingly, since it is possible to suppress the light-emission irregularity on the inside of the convex portion, it is possible to improve the display quality of the electro-optical device.

### Application Example 2

In the electro-optical device according to the application example described above, it is preferable that the sealing layer include a first sealing layer which is formed of a resin material and a second sealing layer which is formed of an inorganic material to cover the first sealing layer, and that the convex portion of the sealing layer be influenced by a shape of the convex portion, which is arranged on the outer edge portion of the first sealing layer to surround the center portion of the first sealing layer.

According to the configuration of this application example, the convex portion of the sealing layer is influenced by the shape of the convex portion of the first sealing layer that configures the sealing layer. Since the first sealing layer is formed of the resin material, it is possible to form the convex portion easily in comparison with a case in which the first sealing layer is formed of an inorganic material.

### Application Example 3

In the electro-optical device according to the application example described above, it is preferable that the convex portion of the sealing layer be provided to surround a region in which the light-emitting elements are arranged in plan view on the periphery of the region, and that the optical layer be arranged closer to an inside of the sealing layer than the convex portion.

According to the configuration of this application example, the convex portion of the sealing layer is provided to surround the light-emitting region on which the light-emitting elements are arranged in plan view on the periphery of the light-emitting region, and the optical layer is arranged closer to the inside than the convex portion. Accordingly, it is possible to render the film thickness of the optical layer within the light-emitting region uniform.

### Application Example 4

In the electro-optical device according to the application example described above, it is preferable that a thickness of the convex portion of the sealing layer be 50% to 400% of a thickness of the optical layer.

When the thickness of the convex portion of the sealing layer is less than 50% of the thickness of the optical layer, it becomes difficult to suppress the spreading of the resin material, which is arranged inside the convex portion in order to form the optical layer, to the outside. On the other hand, when the thickness of the convex portion of the sealing layer increases to the extent that the thickness exceeds 400% of the thickness of the optical layer, since the width of the convex portion increases, the outer peripheral portion of the sealing layer spreads further to the outside and the frame region increases in size. According to the configuration of this application example, since the thickness of the convex portion of the sealing layer is 50% to 400% of the thickness of the optical layer, it is possible to suppress the size of the frame region to be small while suppressing the spreading of the resin material, which is arranged inside the convex portion in order to form the optical layer, to the outside.

### Application Example 5

In the electro-optical device according to the application example described above, the optical layer may include a layer in which two or more layers are laminated together.

According to the configuration of this application example, since the optical layer contains a layer in which two or more layers are laminated together, it is possible to provide the electro-optical device in which the optical layer is configured using two or more layers that have different functions.

### Application Example 6

In the electro-optical device according to the application example described above, the optical layer may include a color filter layer.

According to the configuration of this application example, by providing the color filters as the optical layer, it is possible to provide the electro-optical device that is capable of display or light emission in a specific color of light or full color.

### Application Example 7

In the electro-optical device according to the application example described above, the optical layer may include a micro lens array.

According to the configuration of this application example, by providing the micro lens array as the optical layer, it is possible to provide the electro-optical device that is capable of concentrating and emitting the light from the light-emitting elements. For example, when using the electro-optical device that is provided with the micro lens array and the color filters, since it is possible to cause the light that is shielded by a light-shielding layer to be incident to the opening portions (the regions of the pixels) of the color filters by concentrating the light using the micro lenses, it is possible to increase the usage efficiency of the light.

### Application Example 8

According to this application example, there is provided an electronic apparatus that includes the electro-optical device according to the application examples described above.

According to this application example, an electronic apparatus that includes the electro-optical device, in which the light-emission irregularity is suppressed and high display quality is obtained, may be provided.

### Application Example 9

According to this application example, there is provided a manufacturing method of an electro-optical device that includes forming light-emitting elements by arranging a first electrode, an organic light-emitting layer and a second electrode on a substrate; forming a sealing layer by laminating a first sealing layer and a second sealing layer onto the light-emitting elements to cover the light-emitting elements, and forming an optical layer by applying a resin material onto the sealing layer. In the forming of the first sealing layer, a convex portion, which has a greater film thickness than that of a center portion, is formed on an outer edge portion of the first sealing layer.

According to the manufacturing method of this application example, a convex portion, which has a greater film thickness than that of a center portion, is formed on an outer edge portion of the first sealing layer. Therefore, since the resin material that is arranged on the inside of the convex portion is prevented from spreading to the outside by the convex portion in the forming of the optical layer, it is possible to render the film thickness of the optical layer that is formed inside of the convex portion uniform in comparison with a case in which the convex portion is not present.

### Application Example 10

In the manufacturing method of the electro-optical device according to the application example described above, it is preferable that, in the forming of the first sealing layer, the resin material be applied via a screen mask that includes a first portion through which the resin material passes and a second portion which is arranged to surround the first portion and through which the resin material does not pass.

According to the manufacturing method of this application example, it is possible to easily provide a convex portion on the outer edge portion of the first sealing layer.

### Application Example 11

In the manufacturing method of the electro-optical device according to the application example described above, it is preferable that a thickness of the second portion of the screen mask be changed.

According to the manufacturing method of this application example, since the amount by which the resin material bulges in the outer edge portion of the first portion changes due to changing the thickness of the second portion of the screen mask, it is possible to adjust the film thickness of the convex portion of the first sealing layer that is formed.

### Application Example 12

In the manufacturing method of the electro-optical device according to the application example described above, it is preferable that an aperture ratio between an outer edge portion and a center portion of the first portion of the screen mask be changed.

According to the manufacturing method of this application example, by changing the aperture ratio, that is, the ratio of the opening area to a unit area between an outer edge portion and a center portion of the first portion of the screen mask, it is possible to change the application amount of the resin material per unit area in the outer edge portion and the center portion of the first portion. Accordingly, it is possible to adjust the difference between the film thickness of the convex portion of the first sealing layer that is formed and the film thickness of a portion of the inside of the convex portion.

### Application Example 13

In the manufacturing method of the electro-optical device according to the application example described above, it is preferable that the forming of the optical layer include forming a plurality of coloring layers, and that, in the forming of the plurality of coloring layers, the coloring layer with the greatest film thickness of the plurality of coloring layers be formed last.

For example, when forming the optical layer, which is arranged such that three colors of coloring layer line up to serve as the plurality of coloring layers, when removing portions other than the necessary portions of the coloring layer that is formed first, the sealing layer, which is the layer below, is exposed at both sides of the preserved portion. Furthermore, when removing portions other than the necessary portions of the coloring layer that is formed subsequently, the sealing layer, which is the layer below, is exposed at one side of the preserved portion, and when removing portions other than the necessary portions of the coloring layer that is formed last, the coloring layers that are formed beforehand are present on both sides of the preserved portion. Here, when removing portions other than the necessary portions, when the sealing layer, which is the layer below, is exposed by at least one side of the preserved portion, there is a likelihood that peeling will occur in the preserved coloring layers, and the greater the thickness of the coloring layers, the greater the risk. According to the manufacturing method of this application example, since the coloring layer with the greatest film thickness of the plurality of coloring layers is formed last, it is possible to suppress the risk of peeling occurrence in the coloring layers to be small.

### BRIEF DESCRIPTION OF THE DRAWINGS

The invention will be described with reference to the accompanying drawings, wherein like numbers reference like elements.

FIG. 1 is an equivalent circuit diagram showing the electrical configuration of an organic EL device according to a first embodiment.

FIG. 2 is a schematic plan view showing the configuration of the organic EL device according to the first embodiment.

FIG. 3 is a schematic cross-sectional view taken along line of FIG. 2.

FIG. 4 is an enlarged view of portion IV of FIG. 3.

FIG. 5 is an enlarged view of portion V of FIG. 3.

FIGS. 6A to 6E are schematic views illustrating the manufacturing method of the organic EL device according to the first embodiment.

FIGS. 7A to 7D are schematic views illustrating the manufacturing method of the organic EL device according to the first embodiment.

FIGS. 8A and 8B are schematic views illustrating the configuration of the screen mask.

FIGS. 9A to 9C are schematic views illustrating the configuration of the screen mask.

FIG. 10 a schematic cross-sectional view showing the configuration of the organic EL device according to a second embodiment.

FIG. 11 a schematic view showing the configuration of a head mounted display as the electronic apparatus according to a third embodiment.

FIGS. 12A and 12B are views showing a comparative example of an organic EL device that is provided with a sealing layer of the related art.

### DESCRIPTION OF EXEMPLARY EMBODIMENTS

Hereinafter, the embodiments that embody the invention will be described with reference to the drawings. The drawings used are shown enlarged or reduced, as appropriate, such that the portions being described are visually recognizable. There are also cases in which depiction of components other than those necessary for the description is omitted.

Note that, in the embodiments described hereinafter, when the phrase “on the substrate” is used, for example, this can represent a case in which a part is arranged on the substrate to make contact therewith, a case in which a part is arranged on the substrate via another component, or a case in which a part is arranged on the substrate such that a portion of the part makes contact with the substrate and another portion of the part is arranged on the substrate via another component.

### First Embodiment

### Organic EL Device

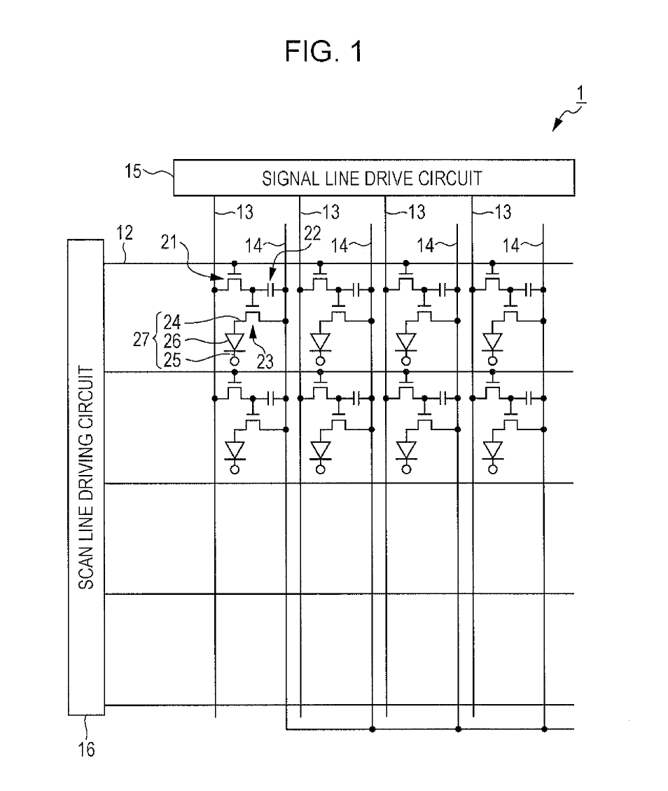

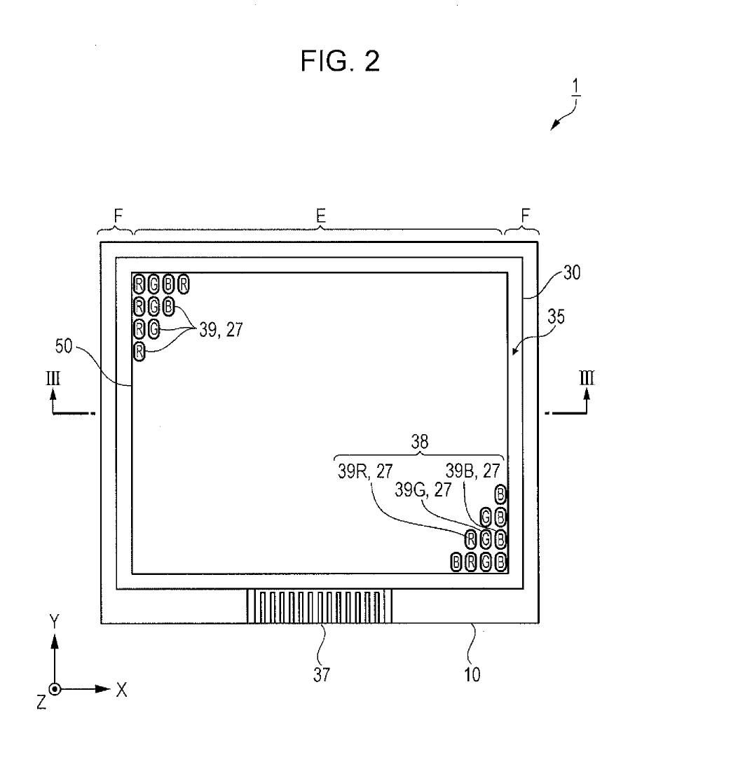

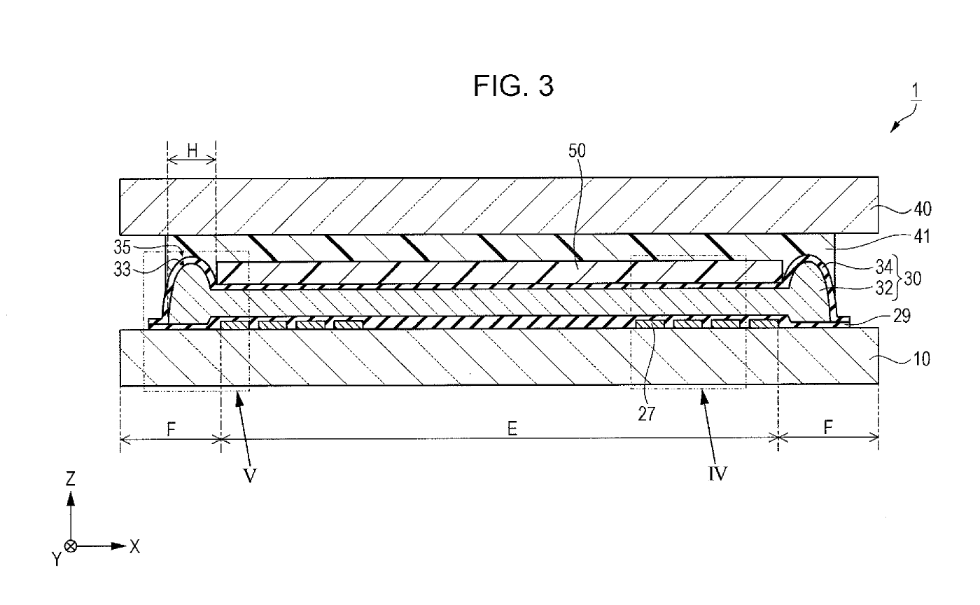

First, description will be given of the configuration of the organic EL device as the electro-optical device according to the first embodiment, with reference to the drawings. FIG. 1 is an equivalent circuit diagram showing the electrical configuration of an organic EL device according to the first embodiment. FIG. 2 is a schematic plan view showing the configuration of the organic EL device according to the first embodiment. Note that, in FIG. 2, depiction of an opposing substrate 40 and an adhesive layer 41 (refer to FIG. 3) is omitted.

As shown in FIG. 1, an organic EL device 1 is an active matrix-type organic EL device using transistors as switching elements. The transistors are, for example, Thin Film Transistors (hereinafter referred to as TFTs) using a thin film semiconductor layer.

The organic EL device 1 is provided with an element substrate 10 (refer to FIG. 2) as the substrate, scan lines 12 that are provided on the element substrate 10, signal lines 13 that extend in a direction that intersects the scan lines 12, and power supply lines 14 that extend parallel to the signal lines 13. The signal lines 13 are connected to a signal line drive circuit 15 that is provided with shift registers, level shifters, video lines and analogue switches. Furthermore, the scan lines 12 are connected to a scan line drive circuit 16 that is provided with shift registers and level shifters.

The regions of sub-pixels 39 (refer to FIG. 2) are partitioned by the scan lines 12 and the signal lines 13. The sub-pixels 39 are the smallest unit of the display of the organic EL device 1. For example, the sub-pixels 39 are set in a matrix-shaped array along the extending direction of the scan lines 12 and the extending direction of the signal lines 13. Each of the sub-pixels 39 is provided with a switching transistor 21, a drive transistor 23, a storage capacitor 22, an anode 24 as a first electrode, a cathode 25 as a second electrode, and a light-emitting functional layer 26 that contains an organic light-emitting layer.

A light-emitting element (an organic EL element) 27 is configured to have the anode 24, the cathode 25 and the light-emitting functional layer 26. In the light-emitting element 27, light emission is obtained due to holes that are injected from the anode 24 side and electrons that are injected from the cathode 25 side reuniting in the organic light-emitting layer of the light-emitting functional layer 26.

In the organic EL device 1, when the switching transistor 21 enters into the ON state due to the scan line 12 being driven, the image signal that is supplied via the signal line 13 is held by the storage capacitor 22, and the conductance state between the source and the drain of the drive transistor 23 is determined according to the state of the storage capacitor 22. When the anode 24 is electrically connected to the power supply line 14 via the drive transistor 23, a current flows from the power supply line 14 to the anode 24, and further, flows therefrom to the cathode 25 via the light-emitting functional layer 26.

The current is of a level corresponding to the conductance state between the source and the drain of the drive transistor 23. At this time, the conductance state between the source and the drain of the drive transistor 23, that is, the conductance state of the channel of the drive transistor 23 is controlled by the potential of the gate of the drive transistor 23. The organic light-emitting layer of the light-emitting functional layer 26 emits light at a luminance corresponding to the amount of current flowing between the anode 24 and the cathode 25.

In other words, when the light emission state of the light-emitting element 27 is controlled by the drive transistor 23, one of the source and the drain of the drive transistor 23 is electrically connected to the power supply line 14, whereas the other of the source and the drain of the drive transistor 23 is electrically connected to the light-emitting element 27.

As shown in FIG. 2, the organic EL device 1 includes, on the element substrate 10, a light-emitting region E of a substantially rectangular planar shape, and a frame region F that surrounds the light-emitting region E on the periphery thereof. The light-emitting region E is a region that actually contributes to the light emission in the organic EL device 1. The frame region F is a region that does not actually contribute to the light emission in the organic EL device 1.

In regard to an electronic apparatus such as a portable apparatus, there is demand for enlarging (widening) the display unit as much as possible in relation to the external shape of the electronic apparatus in order to miniaturize the external shape of the apparatus. Therefore, when the organic EL device 1 is used for the display unit of a miniature electronic apparatus such as a portable apparatus, it is desirable that the light-emitting region E be as big (wide) as possible, and that the frame region F be as small (narrow) as possible in relation to the external shape of the element substrate 10.

The sub-pixels 39 (the light-emitting elements 27) are, for example, set in a matrix-shaped array on the light-emitting region E. Each of the sub-pixels 39 has, for example, a substantially rectangular planar shape. The four corners of each of the substantially rectangular sub-pixels 39 may also be formed in a rounded shape. In this case, the planar shape of the sub-pixel 39 is configured from curved portions that correspond to the four sides and the four corners.

The organic EL device 1 according to this embodiment includes a sub-pixel 39R that emits red (R) light, a sub-pixel 39G that emits green (G) light, and a sub-pixel 39B that emits blue (B) light. Hereinafter, when not distinguishing the corresponding colors, these will simply be referred to as the sub-pixels 39. Each of the sub-pixels 39 is provided with the light-emitting element 27.

A sealing layer 30 is provided on the light-emitting element 27 to cover the light-emitting element 27. The sealing layer 30 is arranged over a wider range than the light-emitting region E. In other words, the outer peripheral portion of the sealing layer 30 is arranged on the frame region F. The sealing layer 30 includes a convex portion 35, which is provided on the outer edge portion thereof in a frame shape in plan view. It is preferable that the convex portion 35 be provided to surround the light-emitting region E on the periphery thereof.

A color filter layer 50 is provided on the sealing layer 30 as an optical layer. The color filter layer 50 is arranged closer to the inside of the sealing layer 30 than the convex portion 35 in plan view to overlap the light-emitting region E on which the light-emitting elements 27 are arranged.

Two circuits, the scan line drive circuit 16 (refer to FIG. 1) and an inspection circuit (not shown) are provided in the periphery of the light-emitting region E. The inspection circuit is a circuit for inspecting the operational status of the organic EL device 1. A cathode wiring (not shown) is arranged on the outer peripheral portion of the element substrate 10. A terminal portion 37 is provided on one side of the element substrate 10. The organic EL device 1 is connected, for example, to a flexible substrate or the like that is provided with a drive IC via the terminal portion 37.

In the organic EL device 1 according to this embodiment, a pixel 38, which is one unit when forming an image, is configured to have the sub-pixels 39R, 39G and 39B. The organic EL device 1 is capable of emitting light of various colors by appropriately changing the luminance of each of the sub-pixels 39R, 39G and 39B in each of the pixels 38. Accordingly, the organic EL device 1 is capable of full color display or full color light emission.

The organic EL device 1 may also be provided with a dummy region, on which the light-emitting elements 27 are arranged, on the outside of the light-emitting region, that is, the frame region F. In this case, the light-emitting elements 27 that are disposed on the dummy region need not be provided with anodes 24. Furthermore, when the organic EL device 1 is provided with a dummy region, the convex portion 35 of the sealing layer 30 is provided to surround the dummy region of the outside of the light-emitting region E on the periphery of the dummy region, and on the inside of the convex portion 35 of the sealing layer 30, the color filter layer 50 is also arranged on the dummy region in addition to the light-emitting region E.

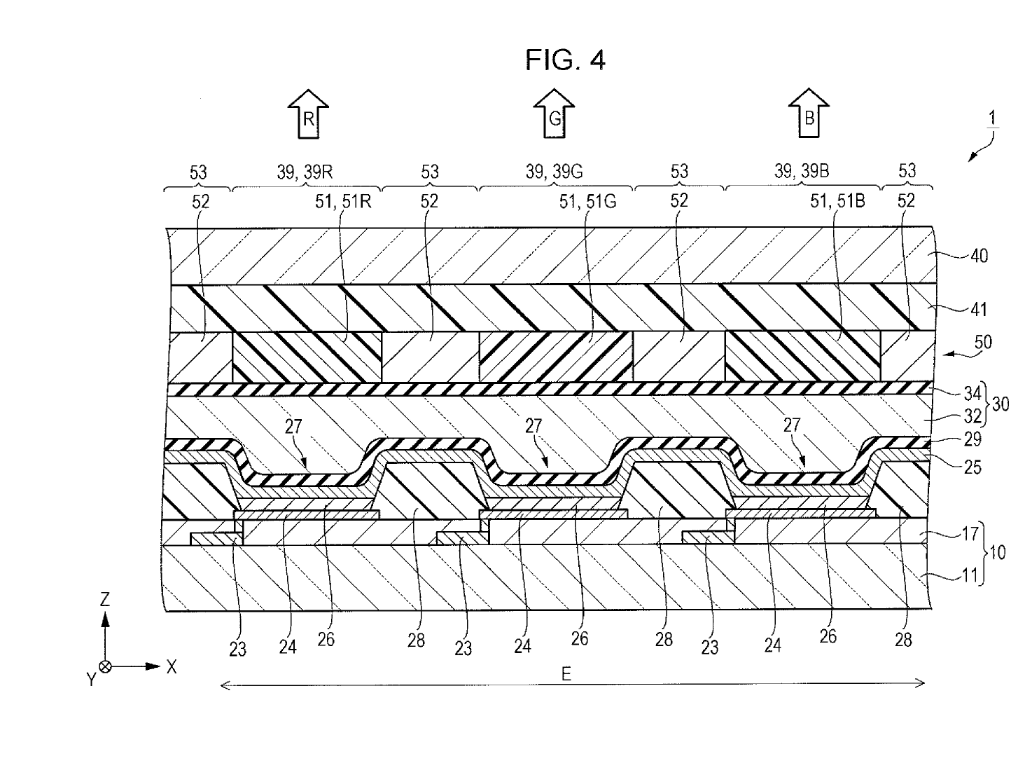

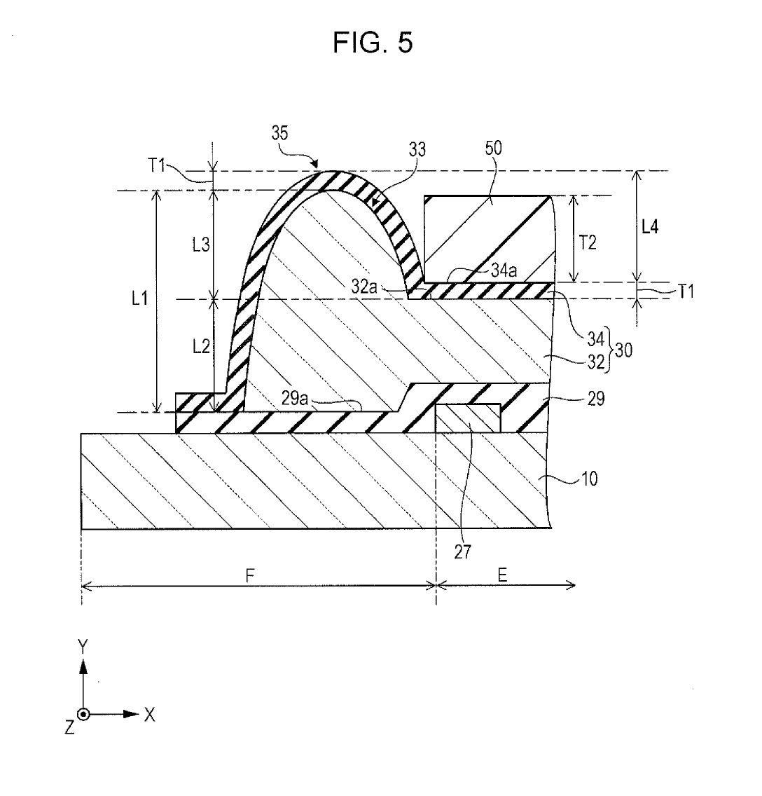

Next, description will be given of the structure of the organic EL device 1 according to a first embodiment with reference to FIGS. 3 to 5. FIG. 3 is a schematic cross-sectional view taken along line of FIG. 2. FIG. 4 is an enlarged view of portion IV of FIG. 3. FIG. 5 is an enlarged view of portion V of FIG. 3.

Description will be given of the schematic structure of the organic EL device 1 with reference to FIG. 3. As shown in FIG. 3, the organic EL device 1 is provided with the element substrate 10, on which the light-emitting elements (the organic EL elements) 27 are provided, the opposing substrate 40, which is arranged to interpose the light-emitting elements 27 between itself and the element substrate 10, and the adhesive layer 41, which is arranged between the element substrate 10 and the opposing substrate 40.

The light-emitting elements 27, partitioning walls 28 (refer to FIG. 4), a cathode protection layer 29, the sealing layer 30 and the color filter layer 50 are provided on the element substrate 10. The organic EL device 1 has a so-called on-chip color filter structure, in which the color filter layer 50 is provided on the element substrate 10.

In this specification, the X direction is a direction parallel to the upper surface of the element substrate 10, and the Y direction is a direction that intersects the upper surface and is perpendicular to the X direction. The Z direction is a direction of the thickness of the element substrate 10 that intersects both the X direction and the Y direction. Note that, as shown in FIG. 2, viewing the organic EL device 1 from the normal line direction (the Z direction) of the upper surface of the element substrate 10 is referred to as “plan view”, and that, as shown in FIG. 3, viewing the cross-section of the organic EL device 1 from the Y direction is referred to as “cross-sectional view”. Furthermore, in FIG. 3, the opposing substrate 40 side (the +Z direction) of the organic EL device 1 is referred to as “upward”, and the element substrate 10 side (the −Z direction) is referred to as “downward”.

The sealing layer 30 according to this embodiment is provided to cover the cathode protection layer 29 on the element substrate 10. The sealing layer 30 is configured to have a buffer layer 32 as the first sealing layer and a gas barrier layer 34 as the second sealing layer.

The buffer layer 32 is provided on the cathode protection layer 29. The buffer layer 32 is formed to overlap the light-emitting region E and such that the outer peripheral portion thereof reaches the frame region F. It is preferable that the outer peripheral portion of the buffer layer 32 be arranged closer to the inside of the cathode protection layer 29 than the outer peripheral portion. The buffer layer 32 includes, on the outer edge portion thereof, a convex portion 33 that is swollen upward. In the buffer layer 32, the convex portion 33 is a portion at which the film thickness is formed thicker than at the center portion. The convex portion 33 is provided to surround the light-emitting region E on the periphery thereof. It is preferable that the convex portion 33 be arranged on the outside of the light-emitting region E, that is, the frame region F.

The gas barrier layer 34 is provided to cover the cathode protection layer 29 and the buffer layer 32. It is preferable that the outer peripheral portion of the gas barrier layer 34 be arranged closer to the outside of the buffer layer 32 than the outer peripheral portion. The gas barrier layer 34 is formed at a substantially uniform film thickness on the buffer layer 32. Therefore, the surface of the gas barrier layer 34 is of a shape that is influenced by the surface of the buffer layer 32 with the convex portion 33. In other words, the sealing layer 30 includes, on the outer edge portion thereof, the convex portion 35 that is influenced by the shape of the convex portion 33 of the buffer layer 32, and the convex portion 35 is arranged to surround the light-emitting region E on the periphery thereof. H is the width (the length in the X direction) from the end of the light-emitting region E side of the convex portion 35 to the end of the buffer layer 32.

The color filter layer 50 is provided on the sealing layer 30 (the gas barrier layer 34). The color filter layer 50 is arranged closer to the inside of the sealing layer 30 than the convex portion 35 to overlap the light-emitting elements 27.

Once the color filter layer 50 is provided on the element substrate 10, the element substrate 10 is fixed to the opposing substrate 40 via the adhesive layer 41. The adhesive layer 41 is, for example, arranged over a range that overlaps the sealing layer 30.

When the organic EL device 1 is of the bottom emission type, in which light emitted from the light-emitting elements 27 is emitted to the lower side of the element substrate 10, a translucent material is used for the element substrate 10. When the organic EL device 1 is of the top emission type, in which light emitted from the light-emitting elements 27 is emitted to the opposing substrate 40 side above the light-emitting elements 27, a translucent material is used for the opposing substrate 40. In this embodiment, the organic EL device 1 is the top emission type.

Description will be given of the detailed structure of the organic EL device 1 with reference to FIG. 4. As shown in FIG. 4, the element substrate 10 includes a substrate main body 11 and a circuit element layer 17. The substrate main body 11 is, for example, formed of glass, quartz, resin, ceramic or the like. The material of the substrate main body 11 may also be silicon (Si). The opposing substrate 40 is, for example, formed of a translucent material such as glass, quartz, resin or ceramic.

The circuit element layer 17 is provided on the substrate main body 11. The circuit element layer 17 contains the drive transistors 23, an inter-layer insulating layer and a planarization layer (neither of which are shown). The drive transistors 23 are provided for each of the sub-pixels 39 (39R, 39G and 39B). Each of the drive transistors 23 are provided with a semiconductor film, a gate insulation layer, a gate electrode, a drain electrode and a source electrode. The gate electrode is arranged to overlap the channel region of the semiconductor film in a planar manner, interposing the gate insulation layer that covers the semiconductor film therebetween.

The drain electrode is conductively connected to the drain region of the semiconductor film via contact holes that are provided in the inter-layer insulating layer that covers the gate electrode and the gate insulation layer. In the same manner, the source electrode is conductively connected to the source region of the semiconductor film via the contact holes. The planarization layer is provided to cover the drain electrodes and the source electrodes; thus, alleviating surface unevenness caused by the electrodes or the other wiring portions.

The anodes 24 are provided for each of the sub-pixels 39 (39R, 39G and 39B) on the element substrate 10. The anodes 24 are configured to contain, for example, metal oxides such as Indium Tin Oxide (ITO) or Indium Zinc Oxide (IZO), metal alloys or the like. The anodes 24 are, for example, each formed in a substantially rectangular shape in plan view. The anodes 24 are electrically connected to the drain electrodes of the drive transistors 23 via the contact holes provided in the circuit element layer 17.

The partitioning walls (banks) 28 are provided on the element substrate 10 in a substantially lattice shaped formation in plan view. The partitioning walls 28, for example, are each the shape of a trapezoid with a cross-sectional shape having inclined surfaces. The partitioning walls 28 are formed to secure the insulating properties between the neighboring anodes 24 and to cover the outer peripheral portions of the anodes 24 by a predetermined width in order to render the shape of the sub-pixels 39 a desired shape (for example, track shaped).

The opening portions of the partitioning walls 28 form the region of the sub-pixels 39. The regions that overlap the partitioning walls 28, that is, the regions other than the region of the sub-pixels 39 form light shielding regions 53. The partitioning walls 28 are, for example, formed of an organic material, which is solvent resistant and heat resistant, such as an acrylic resin or a polyimide resin. The partitioning walls 28 may also, for example, be formed of an inorganic material such as a silicon oxide film (SiO₂).

The light-emitting functional layers 26 are, for example, provided on the anodes 24 in the regions of each of the sub-pixels 39 (39R, 39G and 39B) that are partitioned by the partitioning walls 28. The light-emitting functional layers 26 are, for example, provided with organic light-emitting layers that emit white light. The light-emitting functional layers 26 may also be provided across the entire surface of the light-emitting region E to cover the anodes 24 and the partitioning walls 28.

The light-emitting functional layers 26 include an organic light-emitting layer (an electro-luminescence layer) that is configured of an organic material. The light-emitting functional layers 26 may also be configured to be provided with other layers in addition to the organic light-emitting layer, such as a hole transport layer, a hole injection layer, an electron injection layer, an electron transport layer, a hole blocking layer and an electron blocking layer. When the organic EL device 1 is of the top emission type, the lights of each color emitted from the light-emitting functional layers 26 are emitted upward as shown by the arrows in FIG. 4.

The cathodes 25 are provided on the light-emitting functional layers 26 to cover the partitioning walls 28 and the light-emitting functional layers 26. The cathodes 25 are, for example, configured to contain metals such as calcium (Ca), magnesium (Mg), sodium (Na) and lithium (Li), or by metallic compounds thereof.

The cathode protection layer 29 is provided to cover the cathodes 25 and the cathode wiring (not shown). The cathode protection layer 29 includes a function of protecting the light-emitting elements 27 from oxygen and water. Furthermore, the cathode protection layer 29 also includes a function of protecting the light-emitting elements 27 that contain the cathodes 25 from the organic components contained in the buffer layer 32, which is the layer above. The cathode protection layer 29 is, for example, configured of an inorganic material such as a silicon oxide film (SiO₂), a silicon nitride film (SiN) or a silicon oxynitride film (SiON). The cathode protection layer 29 is, for example, formed using a high-density plasma film formation method such as the ECR sputtering method or the ion plating method.

The buffer layer 32 is provided on the cathode protection layer 29. The buffer layer 32 alleviates stress that is generated by warping or volume expansion of the element substrate 10 and mechanical shock and stress applied to the buffer layer 32 from outside. Therefore, the buffer layer 32 includes a function of preventing the occurrence of cracking and peeling in the gas barrier layer 34, which is the layer above, and the cathode protection layer 29, which is the layer below. The buffer layer 32 includes a function of reducing the parts of the gas barrier layer 34 at which stress is concentrated by alleviating level differences and unevenness in the surface of the cathode protection layer 29 caused by the shape of the partitioning walls 28 in the light-emitting region E, and by substantially planarizing the surface on which the gas barrier layer 34 is formed by film formation.

It is possible to use a translucent resin material such as an epoxy resin, an acrylic resin, a polyurethane resin or a silicone resin, for example, as the material of the buffer layer 32. Of these materials, it is preferable to use an epoxy resin, which constricts (the volume changes) by a small degree when curing.

The gas barrier layer 34 is provided to cover the cathode protection layer 29 and the buffer layer 32. The gas barrier layer 34 includes a function of preventing oxygen or water from permeating the inside thereof. Accordingly, since it is possible to suppress the permeation of oxygen or water to the cathode 25 or the light-emitting functional layer 26, it is possible to suppress degradation or the like of the cathode 25 and the light-emitting functional layer 26. The gas barrier layer 34 is, for example, formed of an inorganic compound such as a silicon oxide film (SiO₂), a silicon nitride film (SiN) or a silicon oxynitride film (SiON). The gas barrier layer 34 is, for example, formed into a film, which is hard and dense, using a high-density plasma film formation method such as the ECR sputtering method or the ion plating method.

The color filter layer 50 is provided on the sealing layer 30 (on the gas barrier layer 34). The color filter layer 50 is configured to have color filters 51 and partitioning walls 52. The color filter layer 50 includes, as the color filters 51, a color filter 51R that transmits red (R) light, a color filter 51G that transmits green (G) light and a color filter 51B that transmits blue (B) light.

The color filters 51R, 51G and 51B are, for example, arranged in striped pattern along the Y direction to correspond to the respective sub-pixels 39R, 39G and 39B. The color filters 51R, 51G and 51B are, for example, formed by patterning a negative-type translucent resin material such as acrylic in which a pigment or the like is dispersed. Hereinafter, when not distinguishing the corresponding colors, these will simply be referred to as the color filters 51.

Pigments matching the light-emitting colors of each of the sub-pixels 39 are dispersed in each of the color filters 51. A material that transmits light of a wavelength range corresponding to red light, that is, light with a wavelength in a range of approximately 610 nm to approximately 750 nm, and absorbs light of any other wavelength range is dispersed in the color filter 51R.

A material that transmits light of a wavelength range corresponding to green light, that is, light with a wavelength in a range of approximately 500 nm to approximately 560 nm, and absorbs light of any other wavelength range is dispersed in the color filter 51G. A material that transmits light of a wavelength range corresponding to blue light, that is, light with a wavelength in a range of approximately 435 nm to approximately 480 nm, and absorbs light of any other wavelength range is dispersed in the color filter 51B.

The partitioning walls 52 partition the regions of each of the color filters 51 that correspond to the regions of each of the sub-pixels 39. In other words, the partitioning walls 52 are arranged in the light shielding regions 53 outside the regions of the sub-pixels 39. The partitioning walls 52 include a function of shielding or reducing the light emitted from the light shielding regions 53, of the light emitted from the light-emitting elements 27. The partitioning walls 52, for example, are arranged in a striped pattern in the Y direction.

A configuration may be adopted in which one of the color filters 51R, 51G or 51B also functions as the partitioning wall 52, and a configuration may also be adopted in which at least two of the color filters 51R, 51G and 51B are laminated to function as the partitioning wall 52. Note that the color filters 51R, 51G and 51B may also be arranged in a matrix pattern. In this case, the partitioning walls 52 may be arranged to be substantially lattice shaped, corresponding to the partitioning walls 28 that partition the regions of the sub-pixels 39.

Once the color filter layer 50 is provided on the element substrate 10, the element substrate 10 is fixed to the opposing substrate 40 via the adhesive layer 41. The adhesive layer 41 is, for example, formed of a translucent adhesive such as an epoxy resin. In addition to fixing the element substrate 10 and the opposing substrate 40 together, the adhesive layer 41 includes a function of alleviating mechanical shock from outside.

Next, further description will be given of the configuration of the sealing layer 30 with reference to FIG. 5. As shown in FIG. 5, L1 is the thickness (the length in the Y direction) of the buffer layer 32 at a portion at which the film thickness is at its greatest. The portion at which the film thickness of the buffer layer 32 is at its greatest is the apex portion of the convex portion 33, and the thickness L1 is the distance in the Y direction between the surface (the upper surface) 29a of the cathode protection layer 29 and the apex of the convex portion 33.

L2 is the thickness (the length in the Y direction) of a substantially planar portion of the inside of the convex portion 33 in the buffer layer 32, and L3 is the thickness (the length in the Y direction) of the convex portion 33 using the substantially planar portion as a reference. The thickness L2 is the distance in the Y direction between a surface 29a of the cathode protection layer 29 and a surface (an upper surface) 32a of the substantially planar portion of the buffer layer 32 when the surface (the surface of the buffer layer 32 side) 29a of the cathode protection layer 29 that is arranged on the frame region F is used as the reference surface. The thickness L3 is the distance in the Y direction between the surface 32a of the substantially planar portion of the buffer layer 32 and the apex of the convex portion 33.

L4 is the thickness (the length in the Y direction) of the convex portion 35 of the sealing layer 30. The thickness L4 is the distance in the Y direction between the surface (the upper surface) 34a of the substantially planar portion of the gas barrier layer 34 and the apex of the convex portion 35. Here, it is possible to consider the film thickness of the gas barrier layer 34 to be uniform across the entire region of the gas barrier layer 34 when compared to the thickness L2 of the substantially planar portion of the buffer layer 32 or the thickness L3 of the convex portion 33. T1 is the film thickness of the gas barrier layer 34, and when the film thickness T1 is uniform across the entire region on the buffer layer 32, the equation L4=L3=L1−L2 is satisfied.

In regard to the sealing layer 30, when T2 is the film thickness of the color filter layer 50, it is preferable that the thickness L4 of the convex portion 35 (the thickness L3 of the convex portion 33) be approximately 50% to 400% of the film thickness T2 of the color filter layer 50, and it is more preferable that the thickness L4 be 50% to 200% of the film thickness T2 of the color filter layer 50. This is due to the following reasons.

When the thickness L4 of the convex portion 35 (the thickness L3 of the convex portion 33) is less than 50% of the film thickness T2 of the color filter layer 50, it becomes difficult to suppress the spreading of the resin material, which is arranged inside the convex portion 35, to the outside when forming the color filter layer 50. The method of forming the color filter layer 50 will be described hereinafter.

On the other hand, when the thickness L4 of the convex portion 35 (the thickness L3 of the convex portion 33) is more than 400% of the film thickness T2 of the color filter layer 50, the width of the convex portion 35 (the length in the X direction, represented by H in FIG. 3) also increases in size, relatively. Therefore, the outer peripheral portion of the sealing layer 30 spreads further outside (the outer peripheral portion side of the element substrate 10); thus, as a result, the frame region F increases in size.

Furthermore, it is preferable that the convex portion 35 be arranged closer to the outside (the frame region F) than the light-emitting region E; however, when reducing the size of the frame region F when the width of the convex portion 35 is great, the portion of the convex portion 35 that rises from the surface 34a of the substantially planar portion of the gas barrier layer 34 ends up being arranged on the inside of the light-emitting region E.

According to the configuration of this embodiment, since the thickness L4 of the convex portion 35 (the thickness L3 of the convex portion 33) is 50% to 400% of the film thickness T2 of the color filter layer 50, it is possible to suppress the size of the frame region F to be small while suppressing the spreading of the resin material, which is arranged inside the convex portion 35, to the outside when forming the color filter layer 50. When the thickness L4 of the convex portion 35 (the thickness L3 of the convex portion 33) is less than 200% of the film thickness T2 of the color filter layer 50, it is possible to suppress the frame region F to be smaller.

Note that the thickness L2 of the substantially planar portion of the buffer layer 32 alleviates the level differences and the unevenness of the surface of the cathode protection layer 29 caused by the shape (the thickness) of the partitioning walls 28, and an appropriate thickness as necessary for alleviating the stress from the warping of the element substrate 10 from outside is set. In this embodiment, for example, the thickness L2 of the substantially planar portion of the buffer layer 32 is set to approximately 2 μm and the thickness L3 of the convex portion 33 is set to approximately 2 μm. Accordingly, the thickness L4 of the convex portion 35 is approximately 2 μm, and the thickness L1 of the thickest portion of the buffer layer 32 is approximately 4 μm. When the film thickness T2 of the color filter layer 50 is set to approximately 1.5 μm, the thickness L4 of the convex portion 35 (the thickness L3 of the convex portion 33) is approximately 133% of the film thickness T2 of the color filter layer 50.

### Manufacturing Method of Organic EL Device

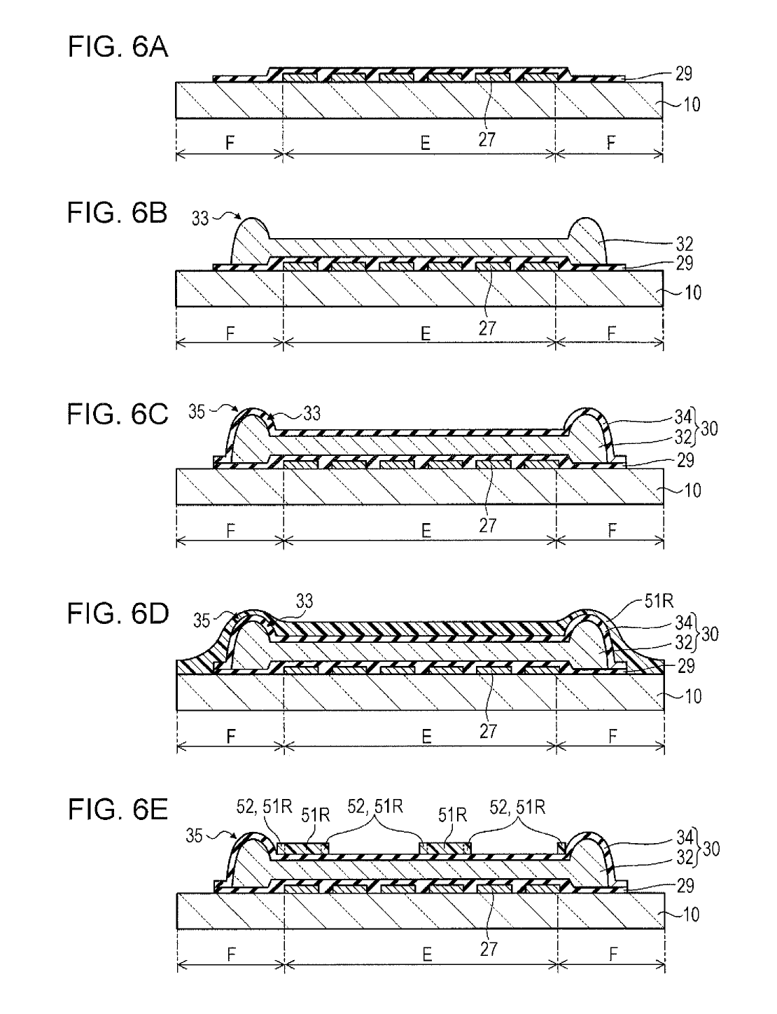

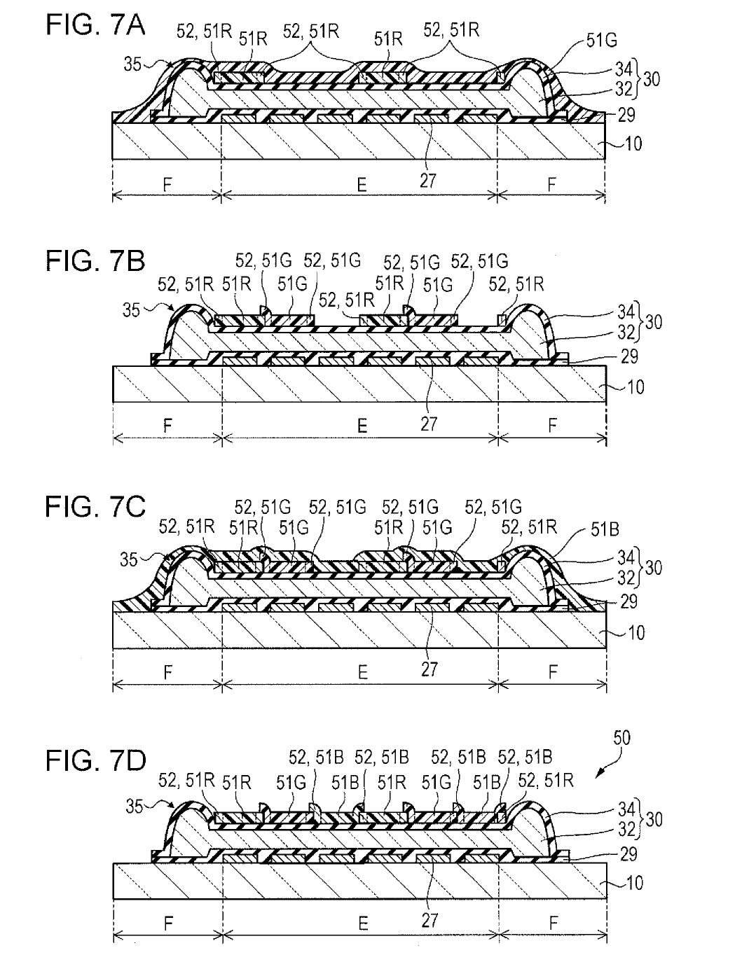

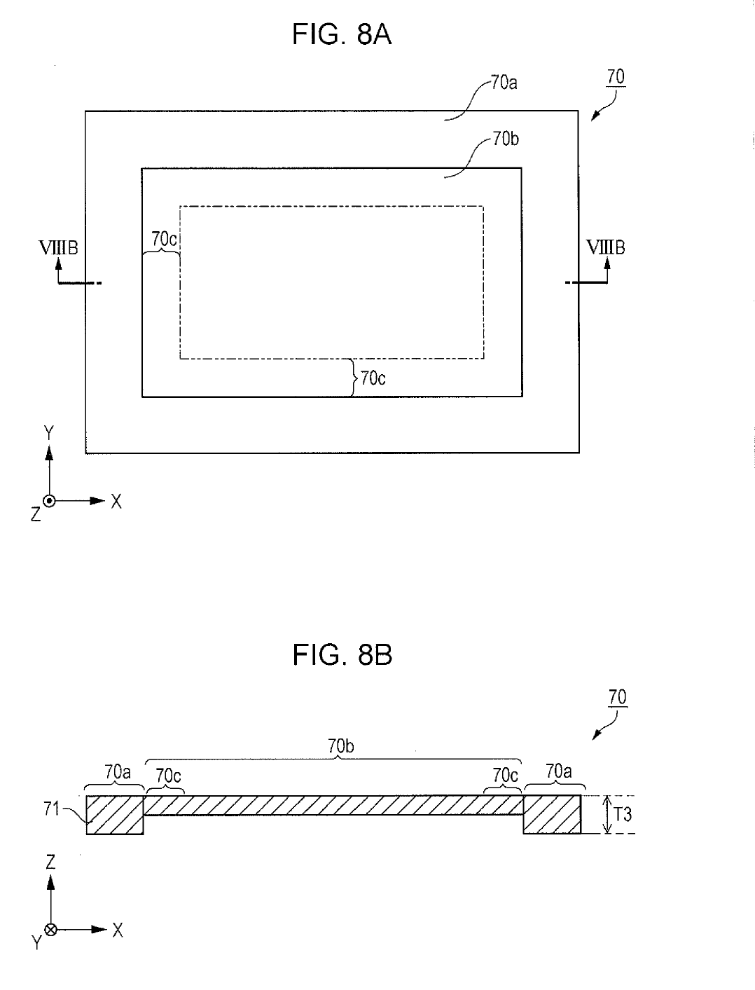

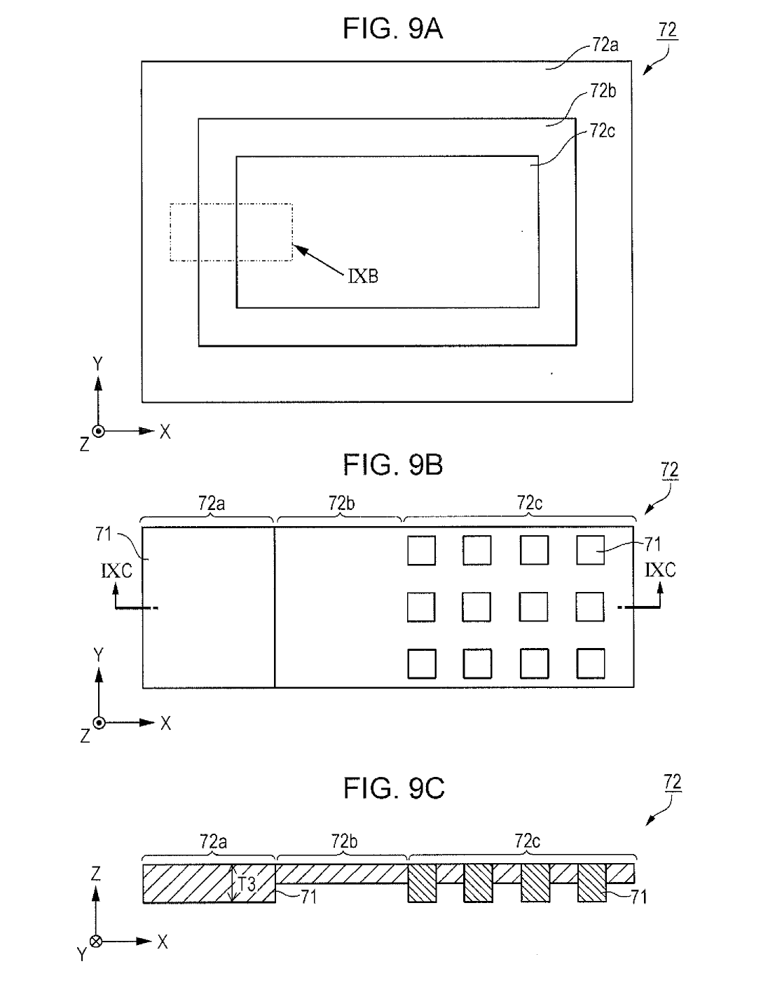

Next, description will be given of the manufacturing method of the organic EL device according to the first embodiment with reference to FIGS. 6A to 9C. FIGS. 6A to 7D are schematic views illustrating the manufacturing method of the organic EL device according to the first embodiment. FIGS. 8A to 9C are schematic views illustrating the configuration of the screen mask.

Note that processing may be carried out on the organic EL device 1 in a large mother substrate state, from which a plurality of the organic EL devices 1 (the element substrates 10) can be taken. A plurality of the organic EL devices 1 may be obtained by finally separating the organic EL devices 1 (the element substrates 10) from the mother substrate by cutting the devices out. FIGS. 6A to 7D show the states of the individual element substrates 10. Note that each of the drawings of FIGS. 6A to 7D is equivalent to a cross-sectional view taken along line of FIG. 2.

First, as shown in FIG. 6A, using well-known technology, the light-emitting elements 27 are formed on the element substrate 10 and the cathode protection layer 29 is formed to cover the light-emitting elements 27. The cathode protection layer 29 is formed such that the outer peripheral portion thereof reaches the frame region F. The cathode protection layer 29 is, for example, formed using a high-density plasma film formation method such as the ECR sputtering method or the ion plating method using an inorganic material such as a silicon oxide film (SiO₂), a silicon nitride film (SiN) or a silicon oxynitride film (SiON).

Next, as shown in FIG. 6B, the buffer layer 32 is formed by applying a resin material onto the element substrate 10 on which the cathode protection layer 29 is formed. The buffer layer 32 is formed to overlap the light-emitting elements 27 and such that the outer peripheral portion thereof reaches the frame region F. It is preferable that the outer peripheral portion of the buffer layer 32 be arranged closer to the inside of the cathode protection layer 29 than the outer peripheral portion.

It is preferable to use an epoxy resin as the resin material for forming the buffer layer 32. By using the epoxy resin, it is possible to suppress the degree of constriction during curing to a small amount in comparison to a case in which another resin material is used. When the degree of constriction during the curing of the resin material is great, the element substrate 10 is more likely to become warped or distorted.

It is possible to use heat curing or UV curing bisphenol A-type epoxy resin or bisphenol F-type epoxy resin for the epoxy resin; however, in this embodiment, it is preferable to use heat curing epoxy resin. The UV curing resin involves a concern that the light-emitting functional layer 26 will be degraded by the irradiation of ultraviolet (UV) light; whereas, the heat curing resin is preferable in that the use thereof does not involve such a risk.

The resin material for forming the buffer layer 32 is, for example, applied using the screen printing method. At this time, it is possible to form the buffer layer 32 and the convex portion 33 at the same time and to adjust the thickness L3 of the convex portion 33 by controlling the wettability of the application surface (the cathode protection layer 29), the thickness T3 of an emulsion 71 that is arranged on the screen mask and the aperture ratio of the screen mask.

As an example, description will be given of a method of forming the convex portion 33 and adjusting the thickness 13 thereof using the wettability of the application surface (the cathode protection layer 29) and the thickness T3 of the emulsion 71 arranged on the screen mask. FIGS. 8A and 8B show the schematic configuration of a screen mask 70 that is used in this embodiment. FIG. 8A is a plan view of the screen mask 70, and FIG. 8B is a schematic cross-sectional view taken along line VIIIB-VIIIB of FIG. 8A.

As shown in FIGS. 8A and 8B, the screen mask 70 includes a first portion 70b and a second portion 70a that is arranged to surround the first portion 70b on the periphery thereof. The first portion 70b is an opening portion that is provided with a mesh or the like through which the resin material passes. The second portion 70a is a non-opening portion on which the emulsion 71 is arranged such that the resin material does not pass therethrough. As shown in FIG. 8B, T3 is the thickness of the emulsion 71 that is arranged on the second portion 70a.

When the resin material is applied to the application surface (the cathode protection layer 29), which is adjusted such that the contact angle of water is 40°, using the screen mask 70, the resin material passes through the screen mask 70 at the first portion 70b and is arranged on the element substrate 10. At this time, the film thickness of a portion of the resin material that is passed through the first portion 70b and corresponds to an outer edge portion 70c is thick in comparison to the film thickness of the center portion. As a result, the convex portion 33 shown in FIG. 6B is formed on the portion of the resin material that is passed through the first portion 70b and corresponds to the outer edge portion 70c. Note that it is preferable that the contact angle of water on the application surface of the resin material be adjusted to 30° to 60°, and it is more preferable that the contact angle be adjusted to 40° to 50°.

In this embodiment, in regard to the wettability of the application surface (the cathode protection layer 29), the contact angle thereof is set to 40° when the liquid is water, the thickness T3 of the emulsion 71 is set to 20 μm and the aperture ratio of the first portion 70b is 100%. Note that the phrase “an aperture ratio of 100%” refers to emulsion or the like not being arranged on the first portion 70b other than the mesh. As a result, it is possible to obtain the buffer layer 32 in which the thickness L3 of the convex portion 33 is 2 μm, the thickness L2 of the substantially planar portion of the buffer layer 32 is 2 μm and the thickness L1 of the thickest portion is 4 μm.

Here, it is possible to increase the thickness L3 of the convex portion 33 by increasing the thickness T3 of the emulsion 71. For example, it is possible to obtain the buffer layer 32 in which the thickness L3 of the convex portion 33 is 6 μm by setting the thickness T3 of the emulsion 71 to 25 μm. In this case, also, since the aperture ratio of the first portion 70b does not change, the thickness L2 of the substantially planar portion of the buffer layer 32 is 2 μm and the thickness L1 of the thickest portion is 8 μm. In this manner, it is possible to adjust the thickness L3 of the convex portion 33 in the buffer layer 32 by changing the thickness T3 of the emulsion 71.

In this embodiment, it is also possible to use a screen mask 72 shown in FIGS. 9A to 9C. FIG. 9A is a plan view of the screen mask 72, FIG. 9B is an enlarged view of portion IXB of FIG. 9A and FIG. 9C is a schematic cross-sectional view taken along line IXC-IXC of FIG. 9A.

As shown in FIG. 9A, the screen mask 72 includes a first portion 72b, a third portion 72c and a second portion 72a. The resin material passes through the first portion 72b and the third portion 72c. The second portion 72a is arranged to surround the first portion 72b on the periphery thereof and resin does not pass therethrough. The first portion 72b has an aperture ratio of 100% and is arranged to surround the third portion 72c on the periphery thereof.

As shown in FIGS. 9B and 9C, the emulsion 71 is arranged partially on the third portion 72c and the aperture ratio thereof is reduced in comparison to that of the first portion 72b. Accordingly, the amount of the resin material per unit area that passes through the third portion 72c is reduced in comparison to that of the first portion 72b. Accordingly, due to the aperture ratio of the third portion 72c being reduced, the film thickness of the resin material that is passed through the first portion 72b becomes thicker than the film thickness of the resin material that is passed through the third portion 72c.

The aperture ratio of the third portion 72c changes according to ratio between the planar area of the portion on which the emulsion 71 is arranged and that of the portion on which the emulsion 71 is not arranged. For example, under the same conditions described above, when the thickness T3 of the emulsion 71 is set to 20 μm and the aperture ratio of the third portion 72c is set to 50%, the thickness L2 of the substantially planar portion of the buffer layer 32 becomes 1 μm. In this case, since the thickness L1 of the portion of the buffer layer 32 at which the film thickness is at its greatest depends on the thickness T3 of the emulsion 71, the thickness L1 becomes 4 μm in the same manner as described above. As a result, the thickness L3 (=L1−L2) of the convex portion 33 is 3 μm. In this manner, it is possible to adjust the thickness L2 of the substantially planar portion of the buffer layer 32 and the thickness L3 of the convex portion 33 by changing the aperture ratio of the third portion 72c.

Note that it is also possible to adjust the thickness L2 of the substantially planar portion of the buffer layer 32 by changing the thickness of the mesh in the first portion 72b and the third portion 72c.

Next, the applied resin material is subjected to heat processing and cured (solidified). Accordingly, the buffer layer 32 is formed.

Next, as shown in FIG. 6C, the gas barrier layer 34 is formed to cover the cathode protection layer 29 and the buffer layer 32. The gas barrier layer 34 is, for example, formed into a film, which is hard and dense, using a high-density plasma film formation method such as the ECR sputtering method or the ion plating method using an inorganic compound such as a silicon oxide film (SiO₂), a silicon nitride film (SiN) or a silicon oxynitride film (SiON). Accordingly, the sealing layer 30 is configured to have the buffer layer 32 and the gas barrier layer 34, and the convex portion 35 that corresponds to the convex portion 33 of the buffer layer 32 is formed. It is preferable that the gas barrier layer 34 be formed such that the outer peripheral portion thereof is arranged closer to the outside of the buffer layer 32 than the outer peripheral portion.

Next, the color filter layer 50 (the color filters 51R, 51G, 51B and the partitioning walls 52) is formed on the sealing layer 30 by carrying out each of the processes shown in FIGS. 6D to 7D.

First, as shown in FIG. 6D, the coloring layer (the color filter) 51R that transmits red light is formed on the element substrate 10 on which the sealing layer 30 is formed. A resin material such as a negative-type photosensitive acrylic, in which a material that transmits light with a wavelength in a range of approximately 610 nm to approximately 750 nm is dispersed, is used as the coloring layer 51R.

The resin material of the coloring layer 51R is, for example, applied to the entire surface on the element substrate 10 using the spin coating method or the slit coating method. The resin material of the coloring layer 51R is arranged to extend over the convex portion 35 of the sealing layer 30. The element substrate 10 to which the resin material is applied is left for a predetermined time, then leveling is performed in order to cause the resin material to spread. At this time, even if the resin material that is arranged on the outside of the convex portion 35 is leveled in the proximity of the level difference between the outer peripheral portion of the sealing layer 30 and the element substrate 10, since the resin material that is arranged on the inside of the convex portion 35 is prevented from spreading to the outside by the convex portion 35, the resin material is leveled on the inside of the convex portion 35. Accordingly, the film thickness of the coloring layer 51R becomes approximately uniform on the inside of the convex portion 35, and it is possible to prevent the film thickness of the coloring layer 51R of the outer edge portion from becoming thin in comparison to the center portion.

Next, as shown in FIG. 6E, the coloring layer 51R is patterned using the photolithography method, and it is possible to selectively remove the coloring layer 51R from regions other than the regions of the red sub-pixels 39R (refer to FIG. 4). A portion that overlaps the convex portion 35 and a portion that is on the outside of the convex portion 35 are selectively removed from the coloring layer 51R. At this time, regions that surround the regions of the sub-pixels 39R, that is, portions that overlap the light shielding regions 53 (refer to FIG. 4) are not removed from the coloring layer 51R and thereby remain. Note that, the photolithography method is a technique in which a target thin film is patterned by sequentially carrying out a developing process and an etching process. In this embodiment, since the target thin film is a photosensitive acrylic, the developing process also acts as the etching process.

Next, the coloring layer 51R that is selectively preserved is cured by being subjected to a heating process. Accordingly, in the inside of the convex portion 35 on the sealing layer 30, the coloring layer 51R that remains in the regions of the red sub-pixels 39R becomes the red color filters 51R. Furthermore, the coloring layer 51R that remains in the light shielding regions 53 functions as the partitioning walls 52.

Next, as shown in FIG. 7A, the coloring layer (the color filter) 51G that transmits green light is formed on the element substrate 10 on which the color filter 51R is formed. A resin material such as a negative-type photosensitive acrylic, in which a material that transmits light with a wavelength in a range of approximately 500 nm to approximately 560 nm is dispersed, is used as the coloring layer 51G.

The resin material of the coloring layer 51G is, for example, applied to the entire surface on the element substrate 10 using the spin coating method or the like. The resin material of the coloring layer 51G is arranged to extend over the convex portion 35 of the sealing layer 30. The element substrate 10 to which the resin material is applied is left for a predetermined time, then leveling is performed in order to cause the resin material to spread. At this time, since the resin material of the coloring layer 51G that is applied to the inside of the convex portion 35 is prevented from spreading to the outside by the convex portion 35, the resin material is leveled on the inside of the convex portion 35. Accordingly, the film thickness of the coloring layer 51G becomes approximately uniform on the inside of the convex portion 35.

Next, as shown in FIG. 7B, the coloring layer 51G is patterned using the photolithography method. Then, the coloring layer 51G is selectively removed from regions other than the regions of the green sub-pixels 39G (refer to FIG. 4). At this time, regions that surround the regions of the sub-pixels 39G, that is, portions that overlap the light shielding regions 53 (refer to FIG. 4) remain in the coloring layer 51G. During the patterning, the red color filters 51R and the partitioning walls 52 (the coloring layer 51R) that are formed on the layer below the coloring layer 51G are already cured, and are therefore not damaged by the etching.

Next, the coloring layer 51G that is selectively preserved is cured by being subjected to a heating process. Accordingly, the coloring layer 51G that remains in the regions of the green sub-pixels 39G becomes the green color filters 51G. Furthermore, the coloring layer 51G that remains in the light shielding regions 53 functions as the partitioning walls 52. As a result, at least a portion of the partitioning walls 52 between the color filters 51R and the color filters 51G is configured by the coloring layer 51G being laminated onto the coloring layer 51R.

Next, as shown in FIG. 7C, the coloring layer (the color filter) 51B that transmits blue light is formed on the element substrate 10 on which the color filters 51R and 51G are formed. A resin material such as a negative-type photosensitive acrylic, in which a material that transmits light with a wavelength in a range of approximately 435 nm to approximately 480 nm is dispersed, is used as the coloring layer 51B.

The resin material of the coloring layer 51B is, for example, applied to the entire surface on the element substrate 10 using the spin coating method or the like. The resin material of the coloring layer 51B is arranged to extend over the convex portion 35 of the sealing layer 30. The element substrate 10 to which the resin material is applied is left for a predetermined time, then leveling is performed in order to cause the resin material to spread. At this time, since the resin material of the coloring layer 51B that is applied to the inside of the convex portion 35 is prevented from spreading to the outside by the convex portion 35, the resin material is leveled on the inside of the convex portion 35. Accordingly, the film thickness of the coloring layer 51B becomes approximately uniform on the inside of the convex portion 35.

Next, as shown in FIG. 7D, the coloring layer 51B is patterned using the photolithography method. Then, the coloring layer 51B is selectively removed from regions other than the regions of the blue sub-pixels 39B (refer to FIG. 4). At this time, regions that surround the regions of the sub-pixels 39B, that is, portions that overlap the light shielding regions 53 remain in the coloring layer 51B.

Next, the coloring layer 51B that is selectively preserved is cured by being subjected to a heating process. Accordingly, the coloring layer 51B that remains in the regions of the blue sub-pixels 39B becomes the blue color filters 51B. Furthermore, the coloring layer 51B that remains in the light shielding regions 53 functions as the partitioning walls 52. As a result, at least a portion of the partitioning walls 52 between the color filters 51G and the color filters 51B is configured by the coloring layer 51B being laminated onto the coloring layer 51G. At least a portion of the partitioning walls 52 between the color filters 51B and the color filters 51R is configured by the coloring layer 51B being laminated onto the coloring layer 51R.

In the processes described above, the order of the processes in which the coloring layers 51R, 51G and 51B are formed is not limited to the process order described above; however, of the coloring layers 51R, 51G and 51B, it is preferable to form the coloring layer in which the film thickness is formed the thickest last.

For example, as shown in FIG. 6E, in the process order described above, when removing portions other than the necessary portions of the coloring layer 51R that is formed first, the sealing layer 30, which is the layer below, is exposed at both sides of the partitioning walls 52 that are formed of the preserved coloring layer 51R. Therefore, there is a likelihood that peeling will occur in the outer peripheral portion of the preserved coloring layer 51R, and the greater the thickness of the coloring layer 51R, the greater the risk.

As shown in FIG. 7B, when removing portions other than the necessary portions of the coloring layer 51G that is formed subsequently, the sealing layer 30, which is the layer below, is exposed at one side of the portions of the partitioning walls 52 that are formed of the preserved coloring layer 51G. Therefore, while the risk of peeling is lower than that of the coloring layer 51R that is formed first, there is a likelihood that peeling will occur at the outer peripheral portion of the preserved coloring layer 51G.

As shown in FIG. 7D, when removing portions other than the necessary portions of the coloring layer 51B that is formed last, one of the coloring layer 51R or the coloring layer 51G that is formed beforehand on both sides of the preserved portion is present. Therefore, in the coloring layer 51B that is formed last, the likelihood that peeling will occur at the outer peripheral portion of the preserved coloring layer 51B is the smallest. Accordingly, when there is no difference in the adhesion to the sealing layer 30, which is the layer below, between each of the different coloring layers, it is preferable that the coloring layer in which the film thickness is formed the thickest be formed last. When there is a difference in the adhesion to the sealing layer 30, which is the layer below, between each of the coloring layers, it is preferable that the coloring layer, which has the lowest adhesion to the sealing layer 30 (peels most easily), be formed last.

According to the processes described above, the color filters 51R, 51G and 51B are formed on the sub-pixels 39R, 39G and 39B, respectively, and the partitioning walls 52 are formed on the light shielding regions 53 that surround the sub-pixels 39R, 39G and 39B, As a result, the color filter layer 50 is formed on the inside of the convex portion 35 on the sealing layer 30.

Of the partitioning walls 52, a portion at which the color filters 51R and the color filters 51G neighbor one another is configured to have the two layers of the coloring layer 51R and the coloring layer 51G. Of the partitioning walls 52, a portion at which the color filters 51G and the color filters 51B neighbor one another is configured to have the two layers of the coloring layer 51G and the coloring layer 51B. Of the partitioning walls 52, a portion at which the color filters 51B and the color filters 51R neighbor one another is configured to have the two layers of the coloring layer 51B and the coloring layer 51R. The coloring layers 51R, 51G and 51B are layers that absorb light other than light in specific wavelength ranges. Accordingly, the partitioning walls 52 that are formed by laminating two layers of the coloring layers have greater light shielding properties than those that are formed using one coloring layer.

In this embodiment, since the partitioning walls 52 are formed of the coloring layers 51R, 51G and 51B that are formed of the resin material, it is possible to reduce the number of times the film forming and patterning processes are carried out in comparison to a case in which the partitioning walls 52 are formed of a different material from the coloring layers 51R, 51G and 51B. In comparison to a case in which the partitioning walls 52 are formed using a metal material, it is possible to form the partitioning walls 52 without carrying out the heating process in the metal film formation process, the wet process (the etching process) in the photolithography process or the like. Accordingly, since it is possible to reduce the influence of the heating process, the wet process or the like on the light-emitting elements 27 that are formed on the element substrate 10, it is possible to manufacture the organic EL device 1 with improved reliability.

Next, after forming the color filter layer 50 in the processes described above, the element substrate 10 and the opposing substrate 40 are fixed by bonding via the adhesive layer 41 using well-known technology. According to the above, it is possible to manufacture the organic EL device 1 shown in FIG. 3.

The organic EL device 1 according to this embodiment has an on-chip color filter structure, in which the color filter layer 50 is formed on the sealing layer 30, and is provided with the sealing layer 30, the outer edge portion of which is provided with the convex portion 35. Here, description will be given of the effects obtained by providing the sealing layer 30 with the convex portion 35 provided thereon in comparison to an organic EL device provided with a sealing layer of the related art.

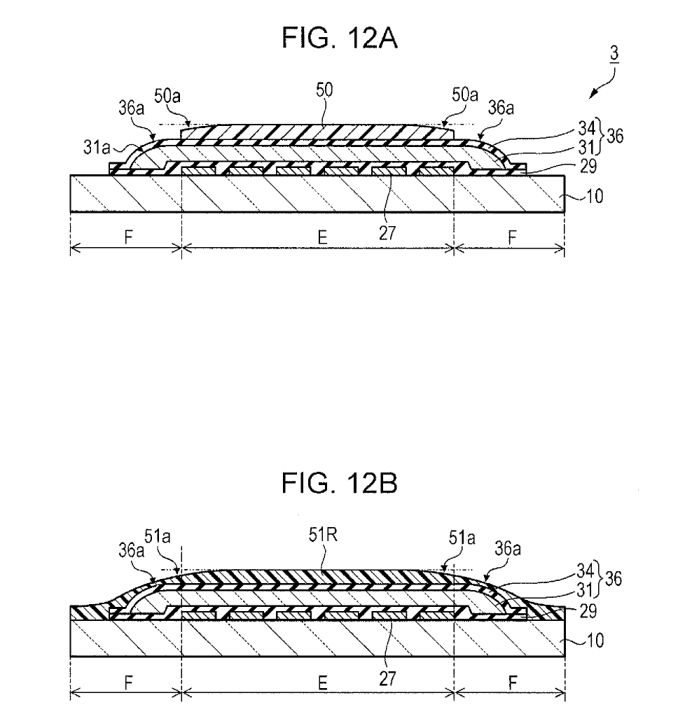

FIGS. 12A and 12B are views showing a comparative example of an organic EL device that is provided with a sealing layer of the related art. Specifically, FIG. 12A is a schematic cross-sectional view of an organic EL device 3, which is the comparative example, and FIG. 12B is a diagram illustrating the process of forming the color filter layer. Note that, in FIG. 12A, depiction of the opposing substrate 40 and the adhesive layer 41 is omitted.

As shown in FIG. 12A, in the organic EL device 3, the light-emitting elements 27, the partitioning walls 28 (not shown), the cathode protection layer 29, a sealing layer 36 and the color filter layer 50 are provided on the element substrate 10. The organic EL device 3 has an on-chip color filter structure in the same manner as the organic EL device 1 according to this embodiment.

The sealing layer 36 is configured to have the buffer layer 31 and the gas barrier layer 34. In comparison to this embodiment, the comparative example is different in that the buffer layer 31 does not include a convex portion on the outer edge portion, that is, that the sealing layer 36 does not include a convex portion on the outer edge portion. More specifically, the thickness of the buffer layer 31 is substantially planar at the center portion; however, in an outer edge portion 31a, the thickness decreases toward the outer peripheral portion. In other words, the film thickness of the buffer layer 31 is thickest at the center portion. Accordingly, the film thickness of the sealing layer 36 is thickest at the center portion and, in the outer edge portion 36a, the thickness decreases toward the outer peripheral portion.

The color filter layer 50 is provided on the sealing layer 36 and is arranged to overlap the light-emitting region E on which the light-emitting elements 27 are arranged. In a portion 50a of the outer edge portion 36a side, the film thickness of the color filter layer 50 is less than that at the center portion thereof. In this manner, when there is a portion within the light-emitting region E at which the film thickness of the color filter layer 50 is different, there is a problem in that light-emission irregularity (color irregularity or luminance irregularity) occurs within the light-emitting region E, causing a reduction in the display quality of the organic EL device 3.

Description will be given of the reason that the film thickness decreases at the portion 50a of the color filter layer 50 in the configuration of the organic EL device 3 with reference to FIG. 12B. FIG. 12B is a diagram illustrating the process of applying the resin material of the coloring layer 51R onto the sealing layer 36 and corresponds to FIG. 6D of this embodiment.

As shown in FIG. 12B, the resin material of the coloring layer 51R is, for example, applied to the entire surface on the element substrate 10 using the spin coating method or the like. When the applied resin material is left for a predetermined time and leveling is performed to cause the resin material to spread, the resin material spreads over the element substrate 10. At this time, since the film thickness of the sealing layer 36 decreases toward the outer peripheral portion at the outer edge portion 36a, the resin material is leveled by spreading from the light-emitting region E to the outer edge portion 36a of the sealing layer 36, and further to the outside of the level difference between the outer peripheral portion of the sealing layer 36 and the element substrate 10. Therefore, the film thickness of the coloring layer 51R that is formed is substantially uniform at the center portion; however, the film thickness is less than that of the center portion at the portion 51a of the outer edge portion 36a side of the sealing layer 36. Accordingly, irregularities occur in the film thickness of the coloring layer 51R within the light-emitting region E.

While not shown in the drawings, in a similar manner, in the process of applying the resin material of the coloring layer 51G (the process that corresponds to FIG. 7A in this embodiment) and the process of applying the resin material of the coloring layer 51B (the process that corresponds to FIG. 7C in this embodiment), irregularities occur in the film thickness of the coloring layers 51G and 51B within the light-emitting region E due to the resin material of the coloring layers 51G and 51B spreading. As a result, as shown in FIG. 12A, irregularities occur in the film thickness of the color filter layer 50 that is formed in a region that overlaps the light-emitting region E.

In order to reduce the irregularity in the film thickness of the color filter layer 50, it is necessary to arrange the outer peripheral portion of the sealing layer 36 (the buffer layer 31) closer to the outside (the end portion side of the element substrate 10); however, as a result, the frame region F increases in size relative to the light-emitting region E.

In contrast, since the organic EL device 1 according to this embodiment is provided with a sealing layer 30, the outer edge portion of which is provided with the convex portion 35, of the resin material of the coloring layers 51R, 51G and 51B that is applied onto the element substrate 10, the resin material that is arranged on the inside of the convex portion 35 accumulates inside the convex portion 35 and is leveled. Accordingly, since the film thickness of the coloring layers 51R, 51G and 51B becomes substantially uniform on the inside of the convex portion 35, it is possible to form the color filter layer 50 with a substantially uniform film thickness. As a result, it is possible to improve the display quality of the organic EL device 1 by suppressing light-emission irregularity while suppressing the frame region F to a small size.

As described above, according to the first embodiment, it is possible to obtain the effects shown hereinafter.

(1) The sealing layer 30 that covers the light-emitting elements 27 includes the convex portion 35, in which the outer edge portion is formed to have a greater film thickness than that of the center portion, and the color filter layer 50 that is formed of a resin material is provided on the sealing layer 30. Therefore, when forming the color filter layer 50, when the resin material of the coloring layer 51 is applied to the entire surface on the element substrate 10, the resin material is arranged to extend over the convex portion 35 of the sealing layer 30; however, even if the resin material that is arranged on the outside of the convex portion 35 is leveled in the proximity of the level difference between the outer peripheral portion of the sealing layer 30 and the element substrate 10, the resin material that is arranged on the inside of the convex portion 35 is prevented from spreading to the outside by the convex portion 35. Accordingly it is possible to render the film thickness of the color filter layer 50 that is formed inside of the convex portion 35 uniform in comparison with a case in which the convex portion 35 is not present. Accordingly, since it is possible to suppress the light-emission irregularity on the inside of the convex portion 35, it is possible to improve the display quality of the organic EL device 1.

(2) The convex portion 35 of the sealing layer 30 is influenced by the shape of the convex portion 33 of the buffer layer 32 that configures the sealing layer 30. Since the buffer layer 32 is formed of the resin material, it is possible to form the convex portion 33 easily in comparison with a case in which the buffer layer 32 is formed of an inorganic material.

(3) the convex portion 35 of the sealing layer 30 is provided to surround the light-emitting region E on which the light-emitting elements 27 are arranged in plan view on the periphery of the light-emitting region E, and the color filter layer 50 is arranged closer to the inside than the convex portion 35. Accordingly, it is possible to render the film thickness of the color filter layer 50 within the light-emitting region E uniform.

(4) When the thickness of the convex portion 35 of the sealing layer 30 is less than 50% of the thickness of the color filter layer 50, it becomes difficult to suppress the spreading of the resin material, which is arranged inside the convex portion 35 in order to form the color filter layer 50, to the outside. On the other hand, when the thickness of the convex portion 35 of the sealing layer 30 increases to the extent that the thickness exceeds 400% of the thickness of the color filter layer 50, since the width of the convex portion 35 increases, the outer peripheral portion of the sealing layer 30 spreads further to the outside and the frame region F increases in size. According to the configuration of this embodiment, since the thickness of the convex portion 35 of the sealing layer 30 is 50% to 400% of the thickness of the color filter layer 50, it is possible to suppress the size of the frame region F to be small while suppressing the spreading of the resin material, which is arranged inside the convex portion 35 in order to form the color filter layer 50, to the outside.

(5) By providing the color filter layer 50 as the optical layer, it is possible to provide the organic EL device 1 that is capable of display or light emission in a specific color of light or full color.

(6) The buffer layer 32 is formed by the screen printing method using the screen masks 70 and 72. At this time, since the resin material bulges at the outer edge portion of the first portions 70b and 72b of the screen masks 70 and 72 due to controlling the wettability of the application surface (the cathode protection layer 29) and the thickness of the emulsion 71 that is arranged on the screen mask, it is possible to easily provide the convex portion 33 on the outer edge portion of the buffer layer 32.

(7) Since the amount by which the resin material bulges in the outer edge portion 70c of the first portion 70b changes due to changing the thickness T3 of the second portion 70a of the screen mask 70, it is possible to adjust the film thickness of the convex portion 33 of the buffer layer 32 that is formed.

(8) In regard to the first portion 72b and the third portion 72c of the screen mask 72, it is possible to change the application amount of the resin material per unit area in the first portion 72b and the third portion 72c by changing the aperture ratio, that is, the ratio of the opening area to a unit area. Accordingly, it is possible to adjust the difference between the film thickness of the convex portion 33 of the buffer layer 32 that is formed and the film thickness of a portion of the inside of the convex portion 33.

(9) When forming the color filter layer 50, which is arranged such that the three colors of coloring layers 51R, 51G and 51B line up, when removing portions other than the necessary portions of the coloring layer 51R that is formed first, the sealing layer 30, which is the layer below, is exposed at both sides of the preserved portion. Furthermore, when removing portions other than the necessary portions of the coloring layer 51G that is formed subsequently, the sealing layer 30, which is the layer below, is exposed at one side of the preserved portion, and when removing portions other than the necessary portions of the coloring layer 513 that is formed last, the coloring layers 51R and 51G that are formed beforehand are present on both sides of the preserved portion. Here, when removing portions other than the necessary portions, when the sealing layer 30, which is the layer below, is exposed by at least one side of the preserved portion, there is a likelihood that peeling will occur in the preserved coloring layers 51R and 51G, and the greater the thickness of the coloring layers 51R and 51G, the greater the risk. According to the manufacturing method of this embodiment, since the coloring layer with the greatest film thickness of the coloring layers 51R, 51G and 51B is formed last, it is possible to suppress the risk of peeling occurrence in the coloring layers to be small.

### Second Embodiment

### Organic EL Device

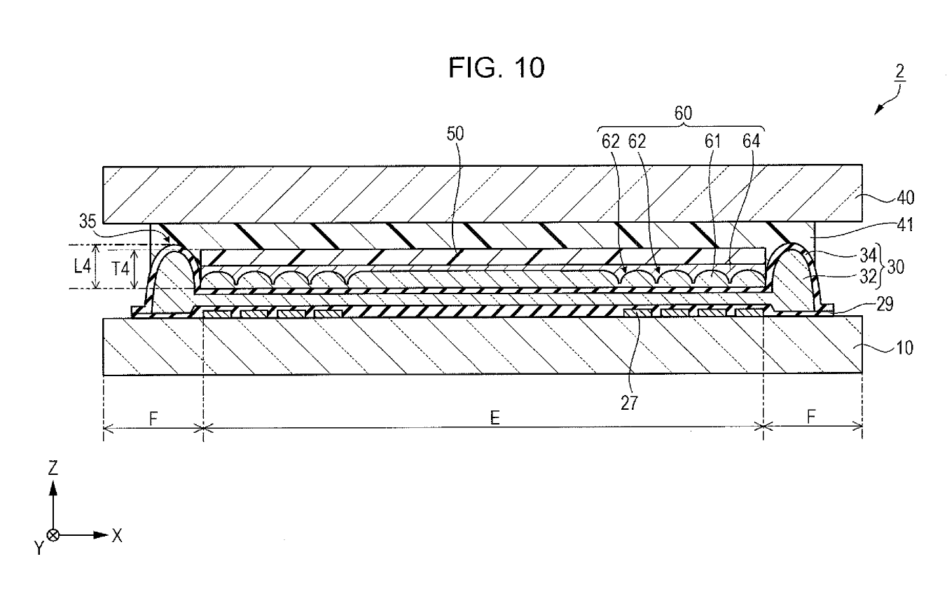

Next, description will be given of the configuration of the organic EL device as the electro-optical device according to the second embodiment, with reference to the drawings. FIG. 10 a schematic cross-sectional view showing the configuration of the organic EL device according to the second embodiment. FIG. 10 corresponds to the cross-sectional view taken along line III-III of FIG. 2.

An organic EL device 2 according to the second embodiment differs from the organic EL device 1 according to the first embodiment in that the organic EL device 2 is provided with two layers of a color filter layer and a micro lens array as the optical layers; however, the other aspects of the configuration are substantially the same. Components that are shared with those of the organic EL device 1 according to the first embodiment are given the same reference numerals and description thereof will be omitted.

As shown in FIG. 10, in the organic EL device 2 according to the second embodiment, the light-emitting elements 27, the partitioning walls 28 (not shown), the cathode protection layer 29, a sealing layer 30, a micro lens array 60 and the color filter layer 50 are provided on the element substrate 10. The micro lens array 60 is provided on the inside of the convex portion 35 on the sealing layer 30. The micro lens array 60 is configured of convex-shaped micro lenses 62 that are formed on a lens layer 61 and an optical path length adjustment layer 64.

The lens layer 61 is, for example, formed of a translucent resin material. The lens layer 61 includes the micro lenses 62 that are formed in convex shapes (for example, a spherical surface shape). The micro lenses 62 are arranged to correspond to each of the sub-pixels 39 (refer to FIG. 2). In other words, the micro lenses 62 are arranged to correspond to each of the light-emitting elements 27 and each of the color filters 51 (refer to FIG. 4). Note that, when the partitioning walls 52 of the color filter layer 50 are formed in a striped pattern, the micro lenses 62 may also be cylindrical lenses that extend along the extending directions of the partitioning walls 52 and the cross section thereof in a direction that intersects the extending directions is formed in a convex shape.

The micro lenses 62 concentrate the light emitted from the light-emitting elements 27 toward the opposing substrate 40 side. In the organic EL device 2, of the light emitted from the light-emitting elements 27, the light that is shielded (or reduced) by the partitioning walls 52 (refer to FIG. 4) of the color filter layer 50 using the micro lenses 62 is concentrated; thus, since it is possible to cause the light to be incident to the color filters 51 (the regions of each of the sub-pixels 39), it is possible to increase the usage efficiency of the light.

The micro lenses 62 are, for example, obtained by forming the lens layer 61 by applying a resin material to the entire surface on the element substrate 10 to cover the sealing layer 30 and forming convex portions (the micro lenses 62) on a portion of the lens layer 61 that is arranged on the inside of the convex portion 35 using a photolithographic method or the like in which a grayscale mask or multi-stage exposures are used. Of the lens layer 61, portions other than that of the inside of the convex portion 35 are removed. Note that, in the center portion in the X direction of the lens layer 61 shown in FIG. 10, depiction of the individual micro lenses 62 is omitted.

The optical path length adjustment layer 64 is provided to cover the lens layer 61. The optical path length adjustment layer 64 is translucent and is formed of a resin material with a different refractive index from that of the lens layer 61. The optical path length adjustment layer 64 includes a function of setting the distance from the micro lenses 62 to the partitioning walls 52 (refer to FIG. 4) of the color filter layer 50 to match a desired value. Accordingly, the layer thickness of the optical path length adjustment layer 64 is set appropriately on the basis of optical conditions such as the focal length of the micro lenses 62.

The optical path length adjustment layer 64 is, for example, obtained by applying a resin material to the entire surface on the element substrate 10 to cover the lens layer 61, then removing portions other than that of the inside of the convex portion 35. The surface (the upper surface) of the optical path length adjustment layer 64 is substantially planar. The color filter layer 50 is provided on the optical path length adjustment layer 64.

In the same manner as in the first embodiment, the color filter layer 50 is formed by applying the resin material of the coloring layers 51R, 51G and 51B (refer to FIGS. 6D, 7A and 7C) to the entire surface on the element substrate 10 to cover the optical path length adjustment layer 64, then subjecting the applied resin material to patterning.

The organic EL device 2 according to the second embodiment is provided with the micro lens array 60 and the color filter layer 50 as the optical layers. When T4 is the total thickness of the optical layers, in which the film thicknesses of the micro lens array 60 and the color filter layer 50 are added together, it is preferable that the thickness L4 of the convex portion 35 be approximately 50% to 400% of the total thickness T4 of the optical layers, and it is more preferable that the thickness L4 be approximately 50% to 200% of the total thickness T4 of the optical layers.

When forming the lens layer 61 and the optical path length adjustment layer 64, the resin material for forming the respective layers is applied to the entire surface on the element substrate 10 using the spin coating method or the like, in the same manner as in the coloring layers 51R, 51G and 51B of the color filter layer 50. Accordingly, of the resin material of the lens layer 61 and the optical path length adjustment layer 64 that is applied onto the element substrate 10, the resin material that is arranged on the inside of the convex portion 35 accumulates inside the convex portion 35 and is leveled. Accordingly, since the film thickness of the lens layer 61 and the optical path length adjustment layer 64 becomes substantially uniform on the inside of the convex portion 35, it is possible to form the lens layer 61 and the optical path length adjustment layer 64 with a substantially uniform film thickness.

The color filter layer 50 is formed on the optical path length adjustment layer 64 and the spreading of the resin material of the coloring layers 51R, 51G and 51B, which are arranged on the inside of the convex portion 35, to the outside is suppressed due to the thickness L4 of the convex portion 35 being 50% to 400% of the total thickness T4 of the optical layers, in which the film thicknesses of the micro lens array 60 and the color filter layer 50 are added together. Accordingly, it is also possible to render the film thickness on the inside of the convex portion 35 substantially uniform in the process of forming the coloring layers 51R, 51G and 51B.

As described above, according to the second embodiment, it is possible to obtain the effects shown hereinafter.

(1) It is also possible to suppress light-emission irregularity and improve the display quality in the same manner as in the first embodiment in the organic EL device 2 according to the second embodiment, which is provided with the micro lens array 60 and the color filter layer 50 as the optical layers.

(2) It is possible to provide the organic EL device 2 in which the optical layer is configured using two or more layers that have different functions such as the micro lens array 60 and the color filter layer 50.

(3) By providing the micro lens array 60 as the optical layer, it is possible to concentrate and emit the light from the light-emitting elements 27. When using the organic EL device 2 that is provided with the micro lens array 60 and the color filter layer 50, since it is possible to cause the light that is shielded by the partitioning walls 52 to be incident to the opening portion (the regions of the sub-pixels 39) of the color filter layer 50 by concentrating the light using the micro lenses 62, it is possible to increase the usage efficiency of the light.

Note that, in the above description, a configuration is adopted in which the micro lens array 60 (the lens layer 61 and the optical path length adjustment layer 64) is formed of a resin material; however, a configuration may also be adopted in which the micro lens array 60 (the lens layer 61 and the optical path length adjustment layer 64) is formed of an inorganic material. In this case, also, it is possible to render the film thickness on the inside of the convex portion 35 substantially uniform in the process in which the coloring layers 51R, 51G and 51B are formed by setting the thickness L4 of the convex portion 35 to 50% to 400% of the total thickness T4 of the optical layers, in which the film thicknesses of the micro lens array 60 and the color filter layer 50 are added together.

A configuration may also be adopted in which the organic EL device 2 is provided with only the micro lens array 60 as the optical layer. For example, when the light-emitting elements 27 of the organic EL device 2 include the light-emitting functional layers 26 that emit light of each of the colors red (R), green (G) and blue (B), the color filter layer 50 may be omitted. In this manner, when the optical layer is configured of only the micro lens array 60, the thickness L4 of the convex portion 35 may be set to 50% to 400% (more preferably, 50% to 200%) of the film thickness of the micro lens array 60 (the lens layer 61 and the optical path length adjustment layer 64).

### Third Embodiment

### Electronic Apparatus

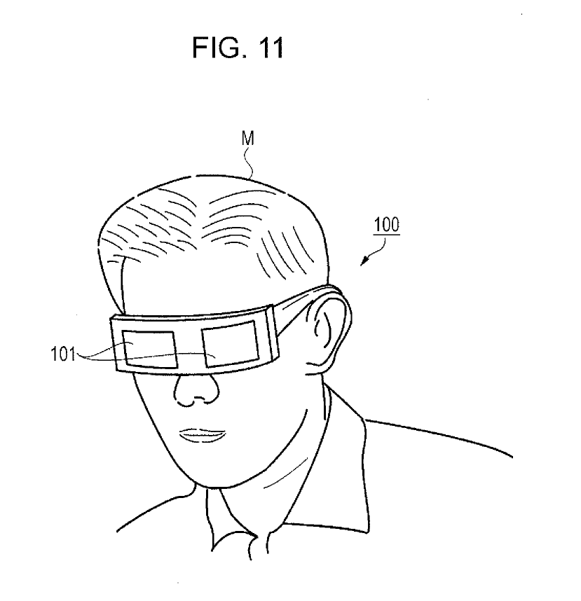

Next, description will be given of an electronic apparatus according to the third embodiment with reference to FIG. 11. FIG. 11 a schematic view showing the configuration of a head mounted display as the electronic apparatus according to the third embodiment.

As shown in FIG. 11, a head mounted display (HMD) 100 according to the third embodiment is provided with two display units 101 that are provided to correspond to the left and right eyes. By wearing the head mounted display 100 on the head in the same manner as a pair of glasses, an observer M is capable of viewing text, images and the like that are displayed on the display units 101. For example, if images that take parallax into account are displayed on the left and right display units 101, it is possible to view and enjoy a stereoscopic picture.

The organic EL device 1 according to the first embodiment or the organic EL device 2 according to the second embodiment is mounted in the display unit 101. Accordingly, it is possible to provide the head mounted display 100 which has both excellent display quality without display irregularities, and is small and light.

The invention is not limited to a configuration in which the head mounted display 100 includes two of the display units 101, and a configuration may also be adopted in which the head mounted display 100 is provided with one of the display units 101 that corresponds to one of the left or the right.

Note that the electronic apparatus, on which the organic EL device 1 according to the first embodiment or the organic EL device 2 according to the second embodiment is mounted, is not limited to the head mounted display 100. Examples of electronic apparatuses that the organic EL device 1 is mounted on include electronic apparatuses that include a display unit such as a personal computer, a portable information terminal, a navigation system, a viewer and a head-up display.

The embodiments described above merely describe a mode of the invention, and may be modified and adapted arbitrarily within the scope of the invention. Modification examples such as those described hereinafter may be considered.

### Modification Example 1

In the organic EL devices 1 and 2 according to the embodiments described above, a configuration is adopted in which the convex portion 33 of the buffer layer 32 is formed using screen printing; however, the invention is not limited to such a mode. For example, a configuration may be adopted in which, after applying the resin material of the buffer layer 32 onto the element substrate 10 using the spin coating method or the like, the applied resin material is processed using a photolithographic method or the like in which a grayscale mask or multi-stage exposures are used to form the convex portion 33.

### Modification Example 2

In the organic EL devices 1 and 2 according to the embodiments described above, a configuration is adopted in which the partitioning walls 52 of the color filter layer 50 are formed of at least one layer of the coloring layers 51R, 51G and 51B; however, the invention is not limited to this mode. The partitioning walls 52 of the color filter layer 50 may be, for example, formed by patterning a resin material in which a black pigment is dispersed or the like. When the partitioning walls 52 are formed of the resin material in which the black pigment is dispersed or the like, it is preferable that the process of forming the partitioning walls 52 be carried out before the process of forming the coloring layers 51R, 51G and 51B.

Even if such a configuration is adopted, it is possible to render the film thickness of the partitioning walls 52 that are formed substantially uniform in the process of forming the partitioning walls 52, since, of the resin material of the partitioning walls 52 that is applied to the entire surface on the element substrate 10, the resin material that is arranged on the inside of the convex portion 35 of the sealing layer 30 accumulates inside the convex portion 35 and is leveled. Accordingly, it is possible to suppress irregularity in the film thickness of the color filter layer 50 and it is possible to render the light shielding (light reduction) properties of the partitioning walls 52 substantially uniform.

### Modification Example 3

In the organic EL devices 1 and 2 according to the embodiments described above, a configuration is adopted in which at least one of the color filter layer 50 or the micro lens array 60 is provided as the optical layer; however, the invention is not limited to this mode. The optical layer may also be, for example, an optical filter that selectively transmits light of a specific wavelength band. Even if such a configuration is adopted, it is possible to render the light transmission properties of the optical filter substantially uniform in the process of forming the optical filter using a resin material, since the resin material accumulates on the inside of the convex portion 35 of the sealing layer 30 and is leveled.

### Modification Example 4

In the organic EL devices 1 and 2 according to the embodiments described above, description is given using a case in which the light-emitting functional layer 26 emits white light or a case in which the light-emitting functional layer 26 emits light of each color of red (R), green (G) and blue (B); however, the invention is not limited to this mode. The organic EL devices 1 and 2 may also have an optically resonant structure that causes light of each of the wavelength bands of red (R), green (G) and blue (B) to resonate.

The entire disclosure of Japanese Patent Application No. 2013-136040, filed Jun. 28, 2013 is expressly incorporated by reference herein.

What is claimed is:

1. An electro-optical device, comprising:
a substrate;
light-emitting elements which are provided above the substrate and contain an organic light-emitting layer;
a sealing layer which is provided above the light-emitting elements; and
an optical layer which is provided above the sealing layer,
wherein the sealing layer includes a convex portion which is arranged on an outer edge portion to surround a center portion of the sealing layer and has a greater film thickness than that of the center portion.

2. The electro-optical device according to claim 1,
wherein the sealing layer includes a first sealing layer which is formed of a resin material and a second sealing layer which is formed of an inorganic material to cover the first sealing layer, and
wherein the convex portion of the sealing layer is influenced by a shape of a convex portion, which is arranged on the outer edge portion of the first sealing layer to surround the center portion of the first sealing layer.

3. The electro-optical device according to claim 2,
wherein the convex portion of the sealing layer is provided to surround a region in which the light-emitting elements are arranged in plan view, and
wherein the optical layer is arranged closer to an inside of the sealing layer than the convex portion.

4. The electro-optical device according to claim 2,
wherein a thickness of the convex portion of the sealing layer is 50% to 400% of a thickness of the optical layer.

5. The electro-optical device according to claim 1,
wherein the optical layer includes a layer in which two or more layers are laminated together.

6. The electro-optical device according to claim 1,
wherein the optical layer includes a color filter layer.

7. The electro-optical device according to claim 1,
wherein the optical layer includes a micro lens array.

8. An electronic apparatus, comprising:
the electro-optical device according to claim 1.

9. An electronic apparatus, comprising:
the electro-optical device according to claim 2.

10. An electronic apparatus, comprising:
the electro-optical device according to claim 3.

11. An electronic apparatus, comprising:
the electro-optical device according to claim 4.

12. An electronic apparatus, comprising:
the electro-optical device according to claim 5.

13. An electronic apparatus, comprising:
the electro-optical device according to claim 6.

14. An electronic apparatus, comprising:
the electro-optical device according to claim 7.

15. A manufacturing method of an electro-optical device, comprising:
forming light-emitting elements by arranging a first electrode, an organic light-emitting layer and a second electrode on a substrate;
forming a sealing layer by laminating a first sealing layer and a second sealing layer onto the light-emitting elements to cover the light-emitting elements, and
forming an optical layer by applying a resin material onto the sealing layer,
wherein, in the forming of the first sealing layer, a convex portion, which has a greater film thickness than that of a center portion, is formed on an outer edge portion of the first sealing layer.

16. The manufacturing method of the electro-optical device according to claim 15,
wherein, in the forming of the first sealing layer, the resin material is applied via a screen mask that includes a first portion through which the resin material passes and a second portion which is arranged to surround the first portion and through which the resin material does not pass.

17. The manufacturing method of the electro-optical device according to claim 16,
wherein a thickness of the second portion of the screen mask is changed.

18. The manufacturing method of the electro-optical device according to claim 16,
wherein an aperture ratio between an outer edge portion and a center portion of the first portion of the screen mask is changed.

19. The manufacturing method of the electro-optical device according to claim 15,
wherein the forming of the optical layer includes forming a plurality of coloring layers, and
wherein, in the forming of the plurality of coloring layers, the coloring layer with the greatest film thickness of the plurality of coloring layers is formed last.
